(19) United States
(12) Patent Application Publication
(10) Pub. No.: US 2025/0248036 A1
(43) Pub. Date: Jul. 31, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Lina Miao, Wuhan (CN); Liang Xiao, Wuhan (CN); Shu Wu, Wuhan (CN); Xiaoming Meng, Wuhan (CN); Wugen Huang, Wuhan (CN); Mingkang Zhang, Wuhan (CN); Xiaoguang Wang, Wuhan (CN); Qingyi Huang, Wuhan (CN)

(21) Appl. No.: 18/435,703

(22) Filed: Feb. 7, 2024

Related U.S. Application Data
(63) Continuation of application No. PCT/CN2024/074167, filed on Jan. 26, 2024.

(51) Int. Cl. H10B 43/27; H10B 41/27; H10B 41/35; H10B 41/40; H10B 43/35; H10B 43/40

(52) U.S. Cl. CPC H10B 43/27; H10B 41/27; H10B 41/35; H10B 41/40; H10B 43/35; H10B 43/40

(57) ABSTRACT

A three-dimensional (3D) memory device and a method for forming the same are disclosed. In certain aspects, the 3D memory device includes a stack including interleaved conductive layers and dielectric layers, and a channel structure extending through the stack in a first direction. The channel structure includes a memory film and a semiconductor channel that exceeds the memory film in the first direction, and the memory film surrounds the semiconductor channel. An adhesive layer is disposed on and in contact with the semiconductor channel that exceeds the memory film. A conductor layer is disposed on and in contact with the adhesive layer.

### CROSS-REFERENCE TO RELATED APPLICATIONS

This application is a continuation of International Application No. PCT/CN2024/074167, filed on Jan. 26, 2024, entitled “THREE-DIMENSIONAL MEMORY DEVICES AND METHODS FOR FORMING THE SAME,” which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as the feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, the present disclosure provides a three-dimensional (3D) memory device. The 3D memory device may include a memory stack including interleaved conductive layers and dielectric layers, and a channel structure extending through the memory stack in a first direction. The channel structure may include a memory film and a semiconductor channel that exceeds the memory film in the first direction, and the memory film may surround the semiconductor channel. An adhesive layer may be disposed on and in contact with the semiconductor channel that exceeds the memory film. A conductor layer may be disposed on and in contact with the adhesive layer.

In some implementations, the adhesive layer may be in contact with a sidewall of the semiconductor channel that exceeds the memory film.

In some implementations, the adhesive layer may be in contact with the memory stack at one side of the adhesive layer and in contact with the conductor layer at another side of the adhesive layer.

In some implementations, the adhesive layer may include one of a Ti/TiN layer, a Ta/TaN layer, or a composite layer having a conductive material.

In some implementations, a thickness of the adhesive layer nay be between about 50 Å and about 100 Å.

In some implementations, the 3D memory device may include a plurality of peripheral contacts each extending in the first direction and being in contact with the adhesive layer, and a first isolation structure extending through the conductor layer and the adhesive layer and extending in a second direction perpendicular to the first direction. The first isolation structure may include a dielectric material.

In some implementations, the first isolation structure may be arranged between two peripheral contacts of the plurality of peripheral contacts to electrically insulate the two peripheral contacts.

In some implementations, the 3D memory device may include a slit structure extending through the memory stack in the first direction, where the slit structure may include a slit core and an insulating layer surrounding the slit core. The slit core may include a conductive material. The slit core may exceed the insulating layer in the first direction and may be in contact with the adhesive layer.

In some implementations, the adhesive layer may be in contact with a sidewall of the slit core that exceeds the insulating layer.

In some implementations, the insulating layer of the slit structure may be approximately flush with a top surface of the memory stack.

In some implementations, the 3D memory device may include a second isolation structure extending through the conductor layer and stopping at the adhesive layer on the slit structure. The second isolation structure may include a dielectric material.

In some implementations, the memory stack may include a first conductive layer in contact with one side of the adhesive layer opposite to the conductor layer.

In some implementations, the first conductive layer may be a polysilicon layer.

In some implementations, the first conductive layer may be one of the conductive layers of the memory stack that is closest to the adhesive layer.

In some implementations, the first conductive layer may include tungsten.

In some implementations, the semiconductor channel may exceed the first conductive layer in the first direction, and the adhesive layer may be in contact with at least a portion of the first conductive layer.

In some implementations, an upper end of the memory film may be approximately flush with a top surface of the first conductive layer.

In some implementations, an upper end of the memory film may be lower than a top surface of the first conductive layer.

In some implementations, the 3D memory device may include a slit structure extending through the memory stack in the first direction, where the slit structure may include a slit core, the slit core including a conductive material; and the slit core may exceed the first conductive layer in the first direction and may be in contact with the adhesive layer.

In some implementations, the conductor layer may include at least one of aluminum or tungsten.

In some implementations, the 3D memory device may include a peripheral contact extending in the first direction and may be in contact with the adhesive layer.

In some implementations, the adhesive layer may be in contact with a sidewall of the peripheral contact.

In some implementations, the memory stack may include a first conductive layer in contact with the adhesive layer, where the first conductive layer may be a polysilicon layer; and the polysilicon layer may extend in a third direction perpendicular to the first direction. The peripheral contact and the channel structure may penetrate the polysilicon layer.

In one aspect, the present disclosure provides a method for forming a three-dimensional (3D) memory device. The method may include forming a first semiconductor structure that includes a memory stack and a channel structure, the channel structure extending through the memory stack in a first direction and including a memory film and a semiconductor channel, the memory film surrounding the semiconductor channel; removing a portion of the memory film to expose a portion of the semiconductor channel; forming an adhesive layer disposed on and in contact with the exposed portion of the semiconductor channel that exceeds a remaining portion of the memory film; and forming a conductor layer disposed on and in contact with the adhesive layer.

In some implementations, forming the adhesive layer may include forming the adhesive layer in contact with a sidewall of the semiconductor channel that exceeds the memory film.

In some implementations, forming the first semiconductor structure may further include forming a channel hole extending in the first direction through a stack structure, a portion of the stack structure being replaced to form the memory stack; and forming the memory film and the semiconductor channel along a sidewall of the channel hole to form the channel structure. The memory film may include a tunneling layer, a storage layer, and a blocking layer.

In some implementations, the method may further include removing a first portion of the conductor layer and a first portion of the adhesive layer to expose the memory stack and form a first trench, the first trench extending in a second direction perpendicular to the first direction; and filling the first trench with a dielectric material to form a first isolation structure.

In some implementations, forming the first semiconductor structure may further include forming a slit structure extending through the memory stack in the first direction, where the slit structure may include a slit core and an insulating layer surrounding the slit core, and the slit core may include a conductive material. The method may further include removing a portion of the insulating layer at one end of the slit structure to form an exposed slit core that exceeds the insulating layer in the first direction; and forming the adhesive layer may include forming the adhesive layer in contact with the exposed slit core.

In some implementations, forming the adhesive layer may further include forming the adhesive layer in contact with a sidewall of the exposed slit core that exceeds the insulating layer.

In some implementations, the method may further include removing a second portion of the conductor layer to form a second trench to expose the adhesive layer on the slit core, the second trench extending in a second direction perpendicular to the first direction; and filling the second trench with a dielectric material to form a second isolation structure.

In some implementations, removing the portion of the memory film may include removing the portion of the memory film surrounding one end of the semiconductor channel, stopping at the memory stack.

In some implementations, forming the first semiconductor structure may further include forming a first conductive layer above a substrate; and forming the channel structure extending through the first conductive layer into the substrate.

In some implementations, removing the portion of the memory film may include removing the portion of the memory film, stopping at the first conductive layer.

In some implementations, forming the first conductive layer may include forming a polysilicon layer above a substrate; and forming the first semiconductor structure may further include: after forming the polysilicon layer, forming a stack structure including interleaved sacrificial layers and dielectric layers; and replacing the sacrificial layers of the stack structure with conductive layers to form the memory stack.

In some implementations, the polysilicon layer may extend from a memory core region of the 3D memory device, in a second direction perpendicular to the first direction, to a peripheral region of the 3D memory device.

In some implementations, forming the first semiconductor structure may include forming a stack structure including interleaved sacrificial layers and dielectric layers; and forming the first conductive layer may include replacing one of the sacrificial layers that is closest to a substrate with a conductive layer. The first conductive layer may include the conductive layer.

In some implementations, forming the adhesive layer may include forming the adhesive layer in contact with at least a portion of the first conductive layer.

In some implementations, the method may further include before forming the adhesive layer, performing a surface treatment on the exposed portion of the semiconductor channel.

In some implementations, the surface treatment may include a laser activation.

In some implementations, the method may further include forming a second semiconductor structure that includes a peripheral circuit of the 3D memory device; and bonding the first semiconductor structure with the second semiconductor structure.

In some implementations, forming the first semiconductor structure may further include forming a first bonding layer; forming the second semiconductor structure may further include forming a second bonding layer; and bonding the first semiconductor structure and the second semiconductor structure may include bonding the first bonding layer of the first semiconductor structure with the second bonding layer of the second semiconductor structure.

In some implementations, the peripheral circuit of the second semiconductor structure may be coupled with the memory stack of the first semiconductor structure through the first and second bonding layers.

In one aspect, the present disclosure provides a system. The system may include a 3D memory device configured to store data and including a first semiconductor structure including a memory stack including interleaved conductive layers and dielectric layers; a channel structure extending through the memory stack in a first direction, the channel structure including a memory film and a semiconductor channel that exceeds the memory film in the first direction, the memory film surrounding the semiconductor channel; an adhesive layer disposed on and in contact with the semiconductor channel that exceeds the memory film; and a conductor layer disposed on and in contact with the adhesive layer; and a second semiconductor structure including a peripheral circuit bonded with the first semiconductor structure. The system may further include a memory controller coupled to the 3D memory device and configured to control the 3D memory device.

In some implementations, the system may include a host coupled to the memory controller.

In some implementations, the memory controller may be coupled with the 3D memory device through the conductor layer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a side view of a cross-section of a 3D memory device.

FIG. 2A illustrates a flowchart of an exemplary method for forming a 3D memory device, according to some aspects of the present disclosure.

FIG. 2B illustrates a flowchart of another exemplary method for forming a 3D memory device, according to some aspects of the present disclosure.

FIG. 3 illustrates a schematic diagram of an exemplary 3D memory device, according to some aspects of the present disclosure.

FIGS. 4A-4E illustrate a fabrication process for forming an exemplary 3D memory device, according to some aspects of the present disclosure.

FIGS. 5A-5B illustrate various configurations of semiconductor channels each extending beyond a memory film in a channel structure, according to some aspects of the present disclosure.

FIGS. 6A-6E illustrate a fabrication process for forming another exemplary 3D memory device, according to some aspects of the present disclosure.

FIGS. 7A-7E illustrate a fabrication process for forming still another exemplary 3D memory device, according to some aspects of the present disclosure.

FIG. 8 illustrates a block diagram of an exemplary system having a 3D memory device, according to some aspects of the present disclosure.

FIG. 9A illustrates a diagram of an exemplary memory card having a 3D memory device, according to some aspects of the present disclosure.

FIG. 9B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the terms “at least one” and “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the terms “based on” and “according to” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” may refer to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

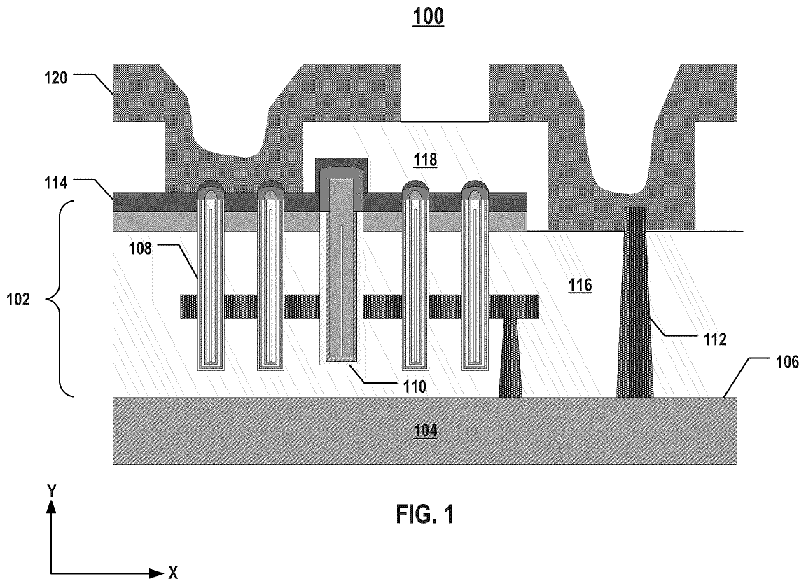

With the increasing layers of 3D memory devices, backside source technology has achieved further performance optimization and cost reduction. This advancement has a significant impact on the semiconductor industry. FIG. 1, for example, illustrates a side view of a cross-section of a 3D memory device 100. As shown in FIG. 1, 3D memory device 100 may include a memory structure 102 bonded with a Complementary Metal-Oxide-Semiconductor (CMOS) structure 104 at a bonding interface 106. Memory structure 102 may include a plurality of semiconductor structures (such as one or more channel structures 108, one or more slit structures 110, one or more contact structures 112, and other components), while semiconductor CMOS structure 104 may include one or more semiconductor circuits (not shown in FIG. 1).

In 3D memory device 100, the copper interface formed in the bonded semiconductor structure and the structure itself may impose certain limitations on post-bonding heat treatment processes. For instance, the fabrication processes may require a bottom polysilicon layer 114 in 3D memory device 100 to be deposited at a relatively lower temperature. Subsequently, a portion of the bottom polysilicon layer 114 may be removed to expose a memory stack 116 at its bottom (in view of the orientation shown in FIG. 1), and an oxide layer 118 may be formed on the remaining bottom polysilicon layer 114 and the exposed memory stack 116. Later, a portion of oxide layer 118 can be removed (e.g., through etching) to form trenches. As a result, one or more conductive materials (e.g., aluminum) may be deposited in the trench to serve as a pad 120 in this backside trench isolation structure.

It is worth noting that the combination of at least the above-identified techniques may contribute to the intricacy of the processes, which can pose challenges in semiconductor production. In addition, issues related to polysilicon activation reflow and material diffusion (e.g., silicon/aluminum diffusion between bottom polysilicon layer 114 and pad 120) may need to be considered and addressed. It is well-known that streamlining semiconductor manufacturing processes can be a crucial goal for enhancing production efficiency and product quality. Therefore, by reducing process complexity, better control over procedures and costs can be expected.

In view of the above-identified drawbacks, the present disclosure introduces one or more solutions in which a portion of a memory film can be removed from a channel structure of memory structure 102, and a conductive material can thus be formed to connect a semiconductor channel and a contact structure. As a consequence, there is no need to grow a film such as bottom polysilicon layer 114 as illustrated in FIG. 1. Accordingly, the backside pad isolation can be omitted. Meanwhile, Gate Induced Drain Leakage (GIDL) activation can be completed through a surface treatment process (e.g., a laser activation) on the exposed surface after the portion of memory film is removed. As a result, the conductive material can replace bottom polysilicon layer 114 and serve as part of the pad structure as well as the backside common source structure. Overall, the backside fabrication processes can be simplified, and the cost can also be reduced.

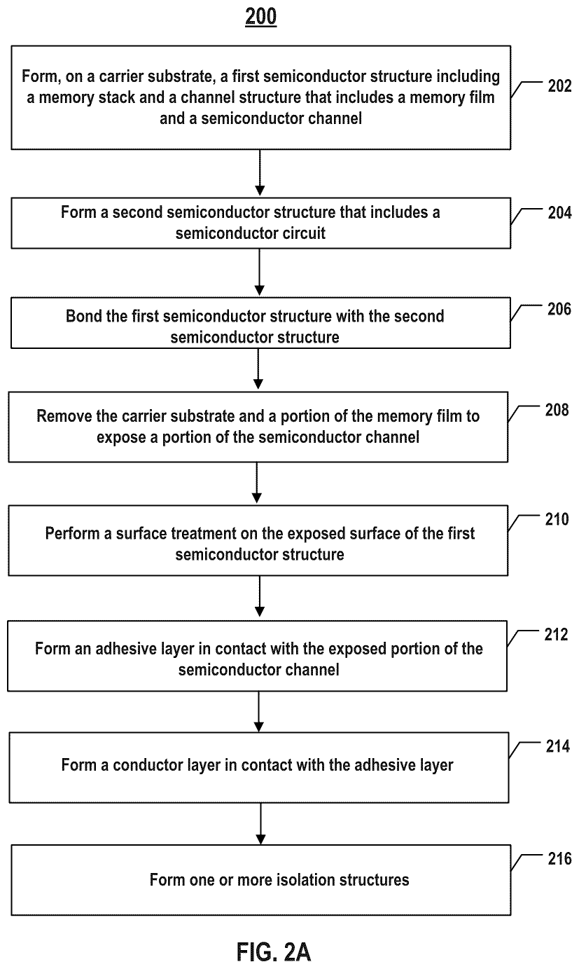

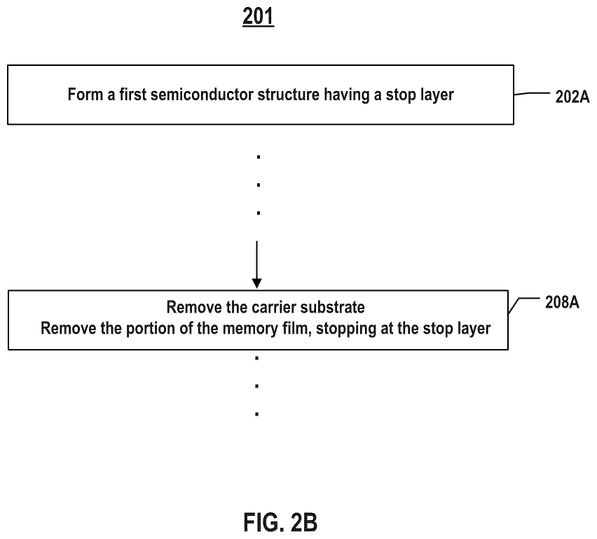

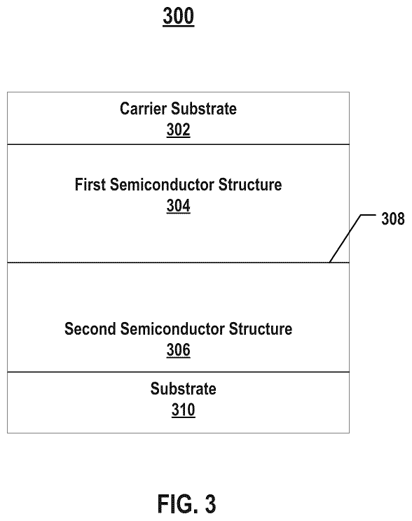

FIG. 2A illustrates a flowchart of an exemplary method 200 for forming a 3D memory device according to some aspects of the present disclosure, while FIG. 3 illustrates a schematic diagram of an exemplary 3D memory device 300 according to some aspects of the present disclosure. It is understood that the operations shown in method 200 are not exhaustive and other techniques can be applied as well before, after, or between any of the illustrated operations. Further, some of the operations in FIG. 2A may be performed simultaneously or in a different order other than those shown in FIG. 2A.

Referring to FIG. 2A, method 200 may start at operation 202, in which a first semiconductor structure 304 (shown in FIG. 3) may be formed on a carrier substrate 302, and at operation 204, a second semiconductor structure 306 may be formed on another substrate 310. In some implementations, first and second semiconductor structures 304 and 306 may be formed sequentially, while in other implementations, they can be formed in a parallel manner. Subsequently, at operation 206, first semiconductor structure 304 on carrier substrate 302 may be bonded with second semiconductor structure 306 on substrate 310 in a face-to-face bonding manner and form a bonding interface 308, as shown in FIG. 3.

In the present disclosure, the term “face-to-face bonding” may be used to refer to first semiconductor structure 304 and second semiconductor structure 306 are bonded in a manner such that carrier substrate 302 and substrate 310 are arranged on the outer sides of the bonded structure, thereby forming bonding interface 308 between first semiconductor structure 304 and second semiconductor structure 306. In some implementations of the present disclosure, the bonding techniques can include hybrid bonding. In some implementations, a treatment process, e.g., a plasma treatment, a wet treatment, and/or a thermal treatment, may be applied to the bonding surface(s) of at least one of first semiconductor structure 304 and second semiconductor structure 306 to improve bonding condition prior to the bonding operation.

Further, the term “memory device” may be used to refer to a bonded chip including first semiconductor structure 304, which may include a memory structure, and second semiconductor structure 306, which may include a semiconductor circuit, e.g., configured to control the memory structure. In some examples, first and second semiconductor structures 304 and 306 may be jointed at bonding interface 308. In some implementations, each of carrier substrate 302 and substrate 310 may include silicon (e.g., single crystalline silicon, c-Si), silicon germanium (SiGe), gallium arsenide (GaAs), germanium (Ge), silicon-on-insulator (SOI), or any other suitable materials.

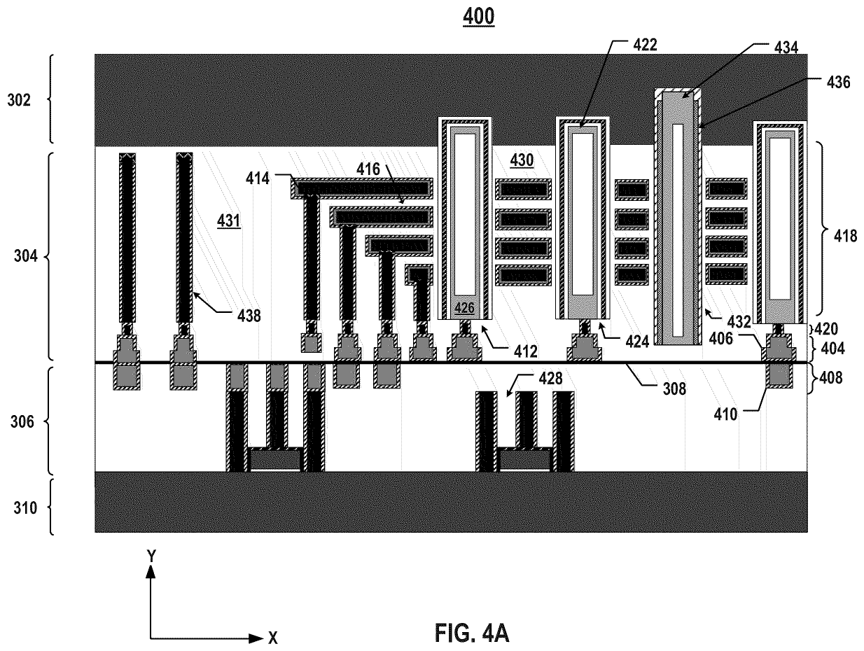

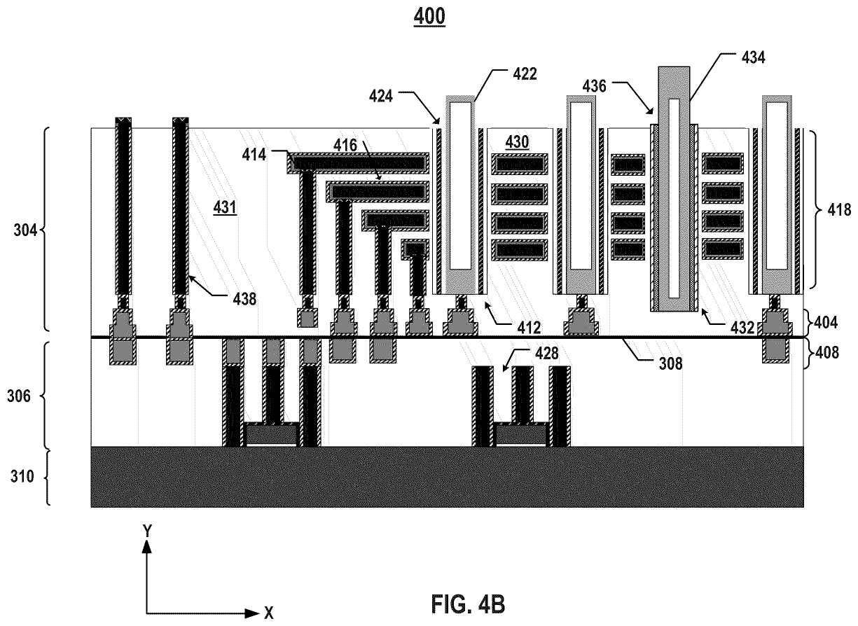

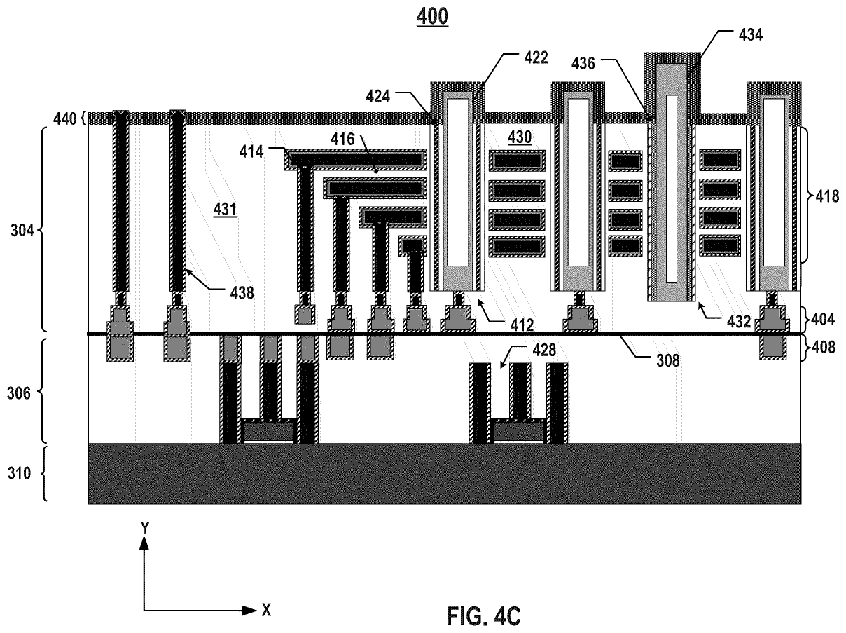

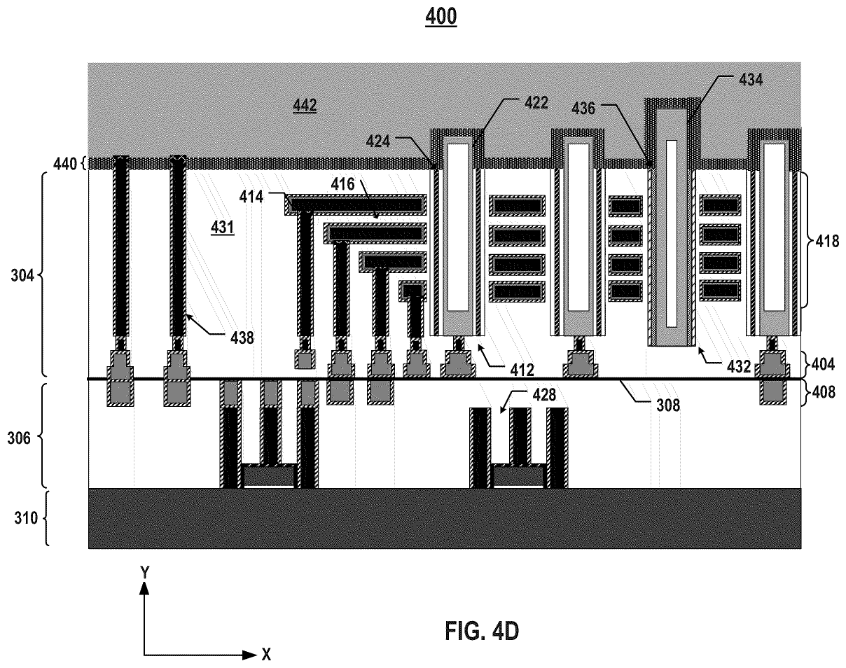

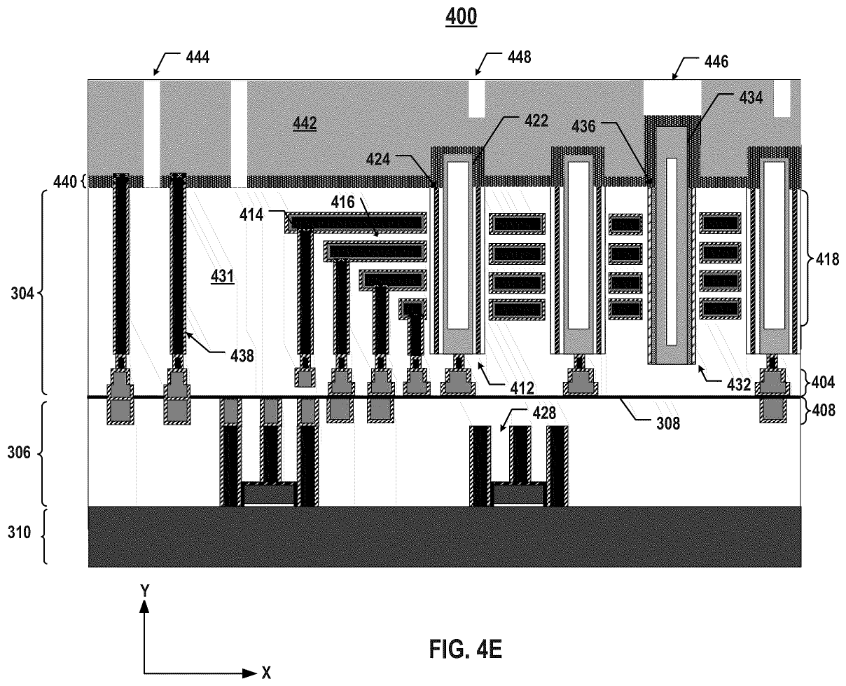

FIGS. 4A-4E illustrate a fabrication process for forming an exemplary 3D memory device 400, according to some aspects of the present disclosure. FIG. 2A and FIGS. 4A-4E will be described together below.

It is obvious that x and y axes in FIGS. 4A-4E are used to illustrate the spatial relationship of the components in 3D memory device 400 having substrate 310 on which second semiconductor structure 306 is formed. Substrate 310 includes two lateral surfaces (e.g., a top surface and a bottom surface) extending laterally in the x-direction (i.e., the lateral direction). As used herein, whether one component (e.g., a layer or a device) is on, above, or below another component (e.g., a layer or a device) of a semiconductor device (e.g., 3D memory device 400) may be determined relative to the substrate of the semiconductor device (e.g., substrate 310) in the y-direction (i.e., the vertical direction) when the substrate is positioned in the lowest plane of the semiconductor device in the y-direction. The same notion for describing spatial relationships may be applied throughout the present disclosure.

After operation 206 in FIG. 2A, a bonded structure of a memory device having first semiconductor structure 304 and second semiconductor structure 306, as shown in FIG. 4A, can be obtained. In some implementations, the memory device may include a 3D memory device 400. In some examples, first semiconductor structure 304 of 3D memory device 400 may include a first bonding layer 404 at bonding interface 308. First bonding layer 404 can include a plurality of first bonding contacts 406 and dielectrics that electrically isolate first bonding contacts 406. First bonding contacts 406 can include conductive materials including, but not limited to, tungsten (W), Cobalt (Co), Copper (Cu), Aluminum (Al), silicides, or any combination thereof. The remaining area of first bonding layer 404 other than first bonding contacts 406 can be formed with the dielectrics including, but not limited to, silicon oxide, silicon nitride, silicon oxynitride, low-k dielectrics, or any combination thereof. First bonding contacts 406 and the surrounding dielectrics in first bonding layer 404 can be used for hybrid bonding.

To form first bonding layer 404, an ILD layer may be deposited using one or more thin film deposition processes, such as chemical vapor deposition (CVD), physical vapor deposition (PVD), atomic layer deposition (ALD), or any combination thereof. In some implementations, first bonding contacts 406 through the ILD layer can be formed using wet etching and/or dry etching, e.g., reactive ion etching (RIE), followed by one or more thin film deposition processes, such as ALD, CVD, PVD, any other suitable processes, or any combination thereof.

Similarly, as shown in FIG. 4A, second semiconductor structure 306 of 3D memory device 400 can include a second bonding layer 408 at bonding interface 308. Second bonding layer 408 of second semiconductor structure 306 can include a plurality of second bonding contacts 410 and dielectrics that electrically isolate second bonding contacts 410. Similarly, second bonding contacts 410 of second semiconductor structure 306 can include conductive materials including, but not limited to, W, Co, Cu, Al, silicides, or any combination thereof. The remaining area of second bonding layer 408 can be formed with the dielectrics including, but not limited to, silicon oxide, silicon nitride, silicon oxynitride, low-k dielectrics, or any combination thereof. Second bonding contacts 410 and the surrounding dielectrics in second bonding layer 408 can be used for hybrid bonding. In some implementations, in the “face-to-face bonding,” second bonding contacts 410 of second semiconductor structure 306 and first bonding contacts 406 of first semiconductor structure 304 may be in direct contact to obtain electrical connections. Second bonding layer 408 and second bonding contacts 410 of second semiconductor structure 306 can be formed similarly to first bonding layer 404 and first bonding contacts 406.

In some implementations, bonding interface 308 can be formed between first bonding layers 404 and 408 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 308 may refer to the location in which first and second bonding layers 404 and 408 are met and bonded. In practice, bonding interface 308 can be a layer with a certain thickness that includes the top surface of first bonding layer 404 of first semiconductor structure 304 and the bottom surface of second bonding layer 408 of second semiconductor structure 306.

In some implementations, first semiconductor structure 304 of 3D memory device 400 may further include an interconnect layer 420 above first bonding layer 404 to transfer electrical signals. Interconnect layer 420 can include a plurality of interconnects, such as middle-end-of-line (MEOL) interconnects and back-end-of-line (BEOL) interconnects. For ease of illustration, interconnect layer 420 in FIG. 4A is simplified as a single layer having certain interconnects. It can be understood that, however, interconnect layer 420 can further include one or more ILD layers in which the interconnect lines and VIA contacts can form. The interconnect lines and VIA contacts in interconnect layer 420 can include conductive materials including, but not limited to W, Co, Cu, Al, silicides, or any combination thereof. The ILD layers in interconnect layer 420 can include dielectric materials including, but not limited to, silicon oxide, silicon nitride, silicon oxynitride, low-k dielectrics, or any combination thereof.

In some implementations, 3D memory device 400 may include a NAND Flash memory device in which memory cells can be provided in the form of an array of NAND memory strings. Each NAND memory string can include a respective channel structure 412. As shown in, e.g., FIG. 4A, each channel structure 412 can extend vertically through a plurality of pairs each including a stack conductive layer 414 and a stack dielectric layer 416. The interleaved stack conductive layers 414 and stack dielectric layers 416 can be part of a memory stack 418. The number of the pairs of stack conductive layers 414 and stack dielectric layers 416 in memory stack 418 may determine the number of memory cells in 3D memory device 400. It is understood that in some implementations, memory stack 418 may have a multi-deck architecture (not shown), which may include a plurality of memory decks stacked over one another. The numbers of the pairs of stack conductive layers 414 and stack dielectric layers 416 in each memory deck can be the same or different. In the attached figures, the numbers of the pairs of stack conductive layers 414 and stack dielectric layers 416 are merely shown for illustrative purposes rather than being used to limit the present disclosure.

As described above, memory stack 418 can include a plurality of interleaved stack conductive layers 414 and stack dielectric layers 416. Stack conductive layers 414 and stack dielectric layers 416 in memory stack 418 can alternate in the vertical direction (i.e., along the y-axis in FIG. 4A). In other words, except the ones at the top or bottom of memory stack 418, each stack conductive layer 414 can be adjoined by two stack dielectric layers 416 on both sides, and each stack dielectric layer 416 can be adjoined by two stack conductive layers 414 on both sides. Stack conductive layers 414 can include conductive materials including, but not limited to, W, Co, Cu, Al, polysilicon, doped silicon, silicides, or any combination thereof. In some implementations, each stack conductive layer 414 can include a gate electrode surrounded by an adhesive layer and a gate dielectric layer. The gate electrode of stack conductive layer 414 can extend laterally as a word line, ending at one or more staircase structures of memory stack 418. Stack dielectric layers 416 can include dielectric materials including, but not limited to, silicon oxide, silicon nitride, silicon oxynitride, or any combination thereof.

In some implementations, each channel structure 412 may be formed through a channel hole filled with a semiconductor layer (e.g., as a semiconductor channel 422) and a composite dielectric layer (e.g., as a memory film 424). In some implementations, semiconductor channel 422 may include silicon, such as amorphous silicon, polysilicon, or single crystalline silicon. In some implementations, memory film 424 may be a composite layer that includes a tunneling layer, a storage layer (a.k.a. “charge trap layer”), and a blocking layer. In one example, the term “memory film” can refer to a composite layer of silicon oxide/silicon oxynitride/silicon oxide (or termed an “ONO” structure), including the tunneling layer, storage layer, blocking layer, and any suitable other layers. The channel hole can be fully or partially filled with a capping layer including dielectric materials, such as silicon oxide, and/or an air gap. Channel structure 412 can have a cylinder shape (e.g., a pillar shape). The capping layer, semiconductor channel 422, the tunneling layer, storage layer, and blocking layer of memory film 424 can be arranged radially from the center toward the outer surface of the pillar in this order, according to some implementations. The tunneling layer can include silicon oxide, silicon oxynitride, or any combination thereof. In some implementations, the storage layer can include silicon nitride, silicon oxynitride, silicon, or any combination thereof. The blocking layer can include silicon oxide, silicon oxynitride, high-k dielectrics, or any combination thereof.

To form memory stack 418, in some implementations, a stack structure including a plurality pairs of a first dielectric layer (referred to herein as “stack sacrificial layer”) and a second dielectric layer (referred to herein as “stack dielectric layer”) may be formed on carrier substrate 302. In the present disclosure, the stack sacrificial layer and the stack dielectric layer together may be referred to as a “dielectric layer pair.” The stack structure may include the interleaved stack sacrificial layers and stack dielectric layers. The stack dielectric layers and the stack sacrificial layers can be alternatingly deposited above carrier substrate 302 to form the stack structure. In some implementations, each stack dielectric layer may include a layer of silicon oxide, and each stack sacrificial layer may include a layer of silicon nitride. The stack structure can be formed by one or more thin film deposition processes including, but not limited to, CVD, PVD, ALD, or any combination thereof.

In some implementations, a staircase structure can be formed on the edge of the stack structure. The staircase structure can be formed by performing a plurality of so-called “trim-etch” cycles to the dielectric layer pairs of stack structure toward carrier substrate 302. Due to the repeated trim-etch cycles applied to the dielectric layer pairs of stack structure, the stack structure can have one or more tilted edges and a top dielectric layer pair shorter than the bottom one, as shown in FIG. 4A.

To form channel structure 412 extending vertically through the stack structure into carrier substrate 302, a plurality of openings can be formed, such that each opening can correspond to a channel hole and can be the location for forming an individual channel structure 412 in the subsequent processes. In some implementations, fabrication processes for forming the channel holes of channel structures 412 may include wet etching and/or dry etching, such as deep RIE (DRIE). The etching of the channel holes continues until being stopped at, e.g., carrier substrate 302, according to some implementations. In some implementations, the etching conditions, such as etching rate and time and the etchants applied, can be controlled to ensure that each channel hole has reached carrier substrate 302. In some implementations, multiple etching operations may be employed, and the subsequent etching operation(s) may be continued until each channel hole reaches carrier substrate 302 to minimize the gouging variations among the channel holes and channel structures 412 formed therein. The present disclosure does not limit thereto.

Subsequently, memory film 424 including a blocking layer, a storage layer, a tunneling layer, and semiconductor channel can be sequentially formed in this order along the sidewall and the bottom surface of the channel hole. In some implementations, the blocking layer, storage layer, and tunneling layer can be first deposited along the sidewall and the bottom surface of the channel hole in this order using one or more thin film deposition processes, such as ALD, CVD, PVD, any other suitable processes, or any combination thereof, to form memory film 424. In some examples, semiconductor channel 422 can then be formed by depositing a semiconductor material, such as polysilicon (e.g., undoped polysilicon), over the tunneling layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (or termed a “SONO” structure) can sequentially be deposited to form the blocking layer, the storage layer, and the tunneling layer of memory film 424 and semiconductor channel 422. As a result, memory film 424 can be formed to surround semiconductor channel 422 at the periphery of semiconductor channel 422.

In some implementations, a capping layer may be formed in the channel hole to fill the channel hole completely or partially. Semiconductor channel 422 may be formed with or without an air gap by adjusting the amount of the filled capping layer. The capping layer can be formed by depositing a dielectric material, such as silicon oxide, using one or more thin film deposition processes, such as ALD, CVD, PVD, any other suitable processes, or any combination thereof. In some implementations, a channel plug 426 can then be formed in the top portion of the channel hole (the “top” orientation being defined before first semiconductor structure 304 is flipped and bonded with second semiconductor structure 306). Channel plug 426 can include semiconductor materials (e.g., polysilicon).

To form channel plug 426, in some implementations, parts of memory film 424, semiconductor channel 422, and the capping layer arranged on the top surface of the stack structure can be removed and planarized by chemical mechanical polishing (CMP), wet etching, and/or dry etching. A recess can then be formed in the top portion of the channel hole by wet etching and/or drying etching parts of semiconductor channel 422 and the capping layer in the top portion of the channel hole. Subsequently, channel plug 426 can be formed by depositing semiconductor materials, such as polysilicon, into the recess by one or more thin film deposition processes, such as CVD, PVD, ALD, or any combination thereof. In some implementations, channel plug 426 may function as the drain of channel structure 412.

To replace the stack structure to form memory stack 418, in some implementations, a slit opening that extends vertically through the stack structure into carrier substrate 302 can be formed. The etching of the slit opening may continue until being stopped at, e.g., carrier substrate 302, according to some implementations. In some implementations, the etching conditions, such as etching rate and time and the etchants applied, can be controlled to ensure that each slit opening has reached carrier substrate 302. In some implementations, fabrication processes for forming the slit opening can include wet etching and/or dry etching, such as DRIE. A gate replacement can then be performed through the slit opening to replace the stack structure with memory stack 418 which includes stack conductive layer 414 and stack dielectric layer 416. In some implementations, a plurality of lateral recesses can be formed by removing the stack sacrificial layers through the slit opening. In some implementations, the stack sacrificial layers can be removed by applying etchants through the slit opening, creating the lateral recesses each interleaved between the stack dielectric layers. The etchants can include any suitable etchants that etch the stack sacrificial layers selective to the stack dielectric layers.

Subsequently, stack conductive layers 414 (may include gate electrodes and adhesive layers) can be deposited into the lateral recesses through the slit opening. In some implementations, a gate dielectric layer may be deposited into the lateral recesses before stack conductive layers 414, such that stack conductive layers 414 can be deposited on the gate dielectric layer. Stack conductive layers 414, such as metal layers (including, e.g., tungsten), can be deposited using one or more thin film deposition processes, such as ALD, CVD, PVD, any other suitable processes, or any combination thereof. In some implementations, the gate dielectric layer, such as a high-k dielectric layer, can be formed along the sidewall and at the bottom of the slit opening as well. Accordingly, memory stack 418 including interleaved stack conductive layers 414 and stack dielectric layers 416 is thereby formed, replacing the stack structure, according to some implementations, as shown in FIG. 4A.

In some implementations, first semiconductor structure 304 of 3D memory device 400 may include a filling layer 430 above memory stack 418, as shown in FIG. 4A. In some implementations, filling layer 430 can include a dielectric material and can be part of memory stack 418, e.g., one of stack dielectric layers 416 closer/closest to carrier substrate 302. In some implementations, the one of stack dielectric layers 416, which serves as filling layer 430 may have a larger thickness than other stack dielectric layers. Alternatively, filling layer 430 can be additionally formed on carrier substrate 302 before forming memory stack 418. In some implementations, filling layer 430 may include one or more pad oxide layers (e.g., silicon oxide layers) between memory stack 418 and carrier substrate 302 to relax the stress between different layers and avoid peeling. In some implementations, filling layer 430 can be formed using one or more thin film deposition processes including, but not limited to, CVD, PVD, ALD, or any combination thereof.

In some implementations, based on the slit opening, a slit structure 432 extending vertically through memory stack 418 (that may include filling layer 430) into carrier substrate 302 can be formed. In some implementations, slit structure 432 can include a slit core 434 (i.e., a conductive layer) within an insulating layer 436, extending along the y-direction, as shown in FIG. 4A. That is, insulating layer 436 may surround slit core 434 at the periphery of slit core 434. In other implementations, slit structure 432 can be formed by fully filling one or more conductive materials, such as polysilicon and/or tungsten, into the slit opening. In still other implementations, slit structure 432 can be formed by fully filling one or more dielectric materials into the slit opening.

In some implementations, to form insulating layer 436 of slit structure 432, one or more dielectric materials may be deposited into the slit opening to partially fill a sidewall of the slit opening using one or more thin film deposition processes, such as ALD, CVD, PVD, any other suitable processes, or any combination thereof. In some examples, the dielectric material may include one or more of silicon oxide, silicon nitride, and silicon oxynitride. Subsequently, a conductive material may be used to fill the remaining space of the slit opening of slit structure 432 to form slit core 434 of slit structure 432. In some implementations, insulating layer 436 may surround the periphery of slit core 434. In some examples, the conductive material for forming slit core 434 may include one or more of polysilicon, silicides, germanium, silicon germanium, copper, aluminum, cobalt, and tungsten. Slit structure 432 may be formed with or without air gap, e.g., by adjusting the amount of the conductive material(s) filled in the slit opening. In some implementations, a glue layer may be formed between slit core 434 and insulating layer 436 to enhance the adhesion of slit core 434 and insulating layer 436. In some implementations, each slit structure 432 can extend laterally to separate a plurality of channel structures 412 into a plurality of memory blocks. That in, memory stack 418 can be divided into a plurality of memory blocks by slit structures 432, such that the array of channel structures 412 can be separated into memory blocks.

In some implementations, second semiconductor structure 306 bonded to first semiconductor structure 304 may include semiconductor circuitry based on CMOS fabrication. In some implementations, the semiconductor circuitry may include a peripheral circuit 428 that is configured to control and sense 3D memory device 400. Peripheral circuit 428 can be any suitable digital, analog, and/or mixed-signal control and sensing circuits used for facilitating the operations of 3D memory device 400 including, but not limited to, a page buffer, a decoder (e.g., a row decoder and a column decoder), a sense amplifier, a driver (e.g., a word line driver), a charge pump, a current or voltage reference, or any active or passive components of the circuit (e.g., transistors, diodes, resistors, or capacitors). Peripheral circuit 428 can include transistors formed on substrate 310, in which the entirety or part of the transistors may be formed in substrate 310 (e.g., below the top surface of substrate 310) and/or directly on substrate 310. In some examples, substrate 310 can be a silicon substrate.

In some examples, the plurality of transistors can be formed on substrate 310 using a plurality of processes including, but not limited to, photolithography, etching, thin film deposition, thermal growth, implantation, CMP, and any other suitable processes. In some implementations, doped regions (not shown) may be formed in substrate 310 by ion implantation and/or thermal diffusion, which function, for example, as source regions and/or drain regions of the transistors. In some implementations, isolation regions can also be formed in substrate 310 by wet etching and/or dry etching and thin film deposition. As a result, the transistors can form peripheral circuit 428 on substrate 310. The transistors are high-speed with advanced logic processes (e.g., technology nodes of 90 nm, 65 nm, 45 nm, 32 nm, 28 nm, 20 nm, 16 nm, 14 nm, 10 nm, 7 nm, 5 nm, 3 nm, 2 nm, etc.), according to some implementations.

Although FIG. 4A does not show the details of peripheral circuit 428, it is apparent that in some implementations, peripheral circuit 428 may further include any other circuits compatible with the advanced logic processes including logic circuits, such as processors and programmable logic devices (PLDs), or memory circuits, such as static random-access memory (SRAM) and dynamic RAM (DRAM).

Similarly, in some implementations, second semiconductor structure 306 of 3D memory device 400 may further include an interconnect layer (not shown) above peripheral circuit 428 to transfer electrical signals to and from peripheral circuit 428. The interconnect layer can include a plurality of interconnects (also herein referred to as contacts), including lateral interconnect lines and vertical interconnect access (VIA) contacts. As used herein, the term “interconnects” can broadly include any suitable types of interconnects, such as MEOL interconnects and BEOL interconnects. The interconnect layer can further include one or more interlayer dielectric (ILD) layers (a.k.a. intermetal dielectric (IMD) layers) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, W, Co, Cu, Al, silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

In some implementations, first semiconductor structure 304 may further include one more peripheral contacts 438 each extending vertically outside a memory core region. In some implementations, first semiconductor structure 304 may include a filling structure 431 in a peripheral region outside the memory core region where memory stack 418 is located, and filling structure 431 may include one or more dielectric materials. In some implementations, each peripheral contact 438 can have a depth greater than the depth of filling structure 431 to extend vertically from first bonding layer 404 of first semiconductor structure 304 into or before carrier substrate 302 in the peripheral region. In some implementations, different from channel structure 412 and slit structure 432 that extend further into carrier substrate 302, peripheral contact 438 may stop at filling structure 431 and may not extend vertically into carrier substrate 302, as shown in FIG. 4A.

Peripheral contact 438 each can include one or more conductive layers, such as a metal layer (e.g., W, Co, Cu, or Al) or a silicide layer surrounded by a glue layer (e.g., a TiN layer). In some implementations, peripheral contact 438 may be configured to electrically couple with second semiconductor structure 306. For example, peripheral contact 438 may be configured to connect with the interconnect layer of second semiconductor structure 306 and electrically coupled with peripheral circuit 428 in second semiconductor structure 306.

After first semiconductor structure 304 having semiconductor memory structure is bonded with second semiconductor structure 306 having a peripheral circuit, method 200 may proceed to operation 208 in FIG. 2A. At operation 208, carrier substrate 302 and a portion of memory film 424 may be sequentially removed to expose a portion of semiconductor channel 422. As illustrated in FIG. 4B, carrier substrate 302 can be completely removed from the backside of memory device 400 (i.e., the top side in FIG. 4B). In some implementations, carrier substrate 302 can be completely removed using CMP, grinding, dry etching, and/or wet etching. In some implementations, carrier substrate 302 may be peeled off. In some implementations in which carrier substrate 302 may include silicon, carrier substrate 302 may be removed using silicon CMP. In some implementations, carrier substrate 302 (a silicon substrate) may be removed using wet etching by tetramethylammonium hydroxide (TMAH).

When/After removing carrier substrate 302, a portion of memory film 424 including the storage layer, blocking layer, and tunneling layer that face and close to carrier substrate 302 can be removed to expose the top portion of semiconductor channel 422 extending beyond memory stack 418. In some implementations, carrier substrate 302 and the portion of memory film 424 can be removed by applying etchants on carrier substrate 302. The etchants can include any suitable etchants that etch carrier substrate 302 selective to channel structure 412 (e.g., semiconductor channel 422). In some implementations, the etching operation(s) may be further performed to remove the portion of memory film 424 of channel structure 412. For example, memory film 424 of channel structure 412 may be etched, stopping at memory stack 418. In some examples, channel structure 412 may extend beyond memory film 424, e.g., about 10 nm. That is, after operation 208, semiconductor channel 422 can exceed memory film 424 in the vertical direction.

At operation 208, in some implementations, multiple wet etching processes may be sequentially performed. For example, the storage layer including silicon nitride can be selectively removed using wet etching with suitable etchants, such as phosphoric acid. Then, the blocking layer and tunneling layer including silicon oxide may be selectively removed using wet etching with suitable etchants, such as hydrofluoric acid, without etching semiconductor channel 422, which includes polysilicon. The etching of the storage layer, blocking layer, and tunneling layer can be controlled by adjusting the etching time and/or etching rate and the etchants, such that the etching does not continue beyond a desired etching depth. That is, the etching of memory film 424 can be controlled such that the upper end of semiconductor channel 422 can exceed the upper end of memory film 424, according to some implementations. In other words, semiconductor channel 422 can extend further beyond memory stack 418 than memory film 424. For example, as shown in FIG. 4B, memory film 424 may end at the top surface of memory stack 418 (e.g., at filling layer 430 of memory stack 418), while semiconductor channel 422 may extend above the top surface of memory stack 418.

In the present disclosure, the terms “exceed” and “extend beyond” may be used interchangeably to describe that the upper end of memory film 424 is below the upper end of semiconductor channel 422 in channel structure 412 along the vertical direction. As shown in FIG. 4B, the upper end of memory film 424 is not aligned with the upper end of semiconductor channel 422 in the vertical direction after the portion of memory film 424 is removed, according to some implementations. In some implementations, the upper end of memory film 424 may be flush with memory stack 418, i.e., the top surface of memory stack 418 including filling layer 430. That is, the vertical level of memory film 424 may be approximately identical to the vertical level of memory stack 418. In some implementations, the upper end of memory film 424 may be below the top surface of memory stack 418 which includes filling layer 430, as shown in FIG. 4B. In other words, the upper end of memory film 424 can be flush with or lower than the top surface of memory stack 418.

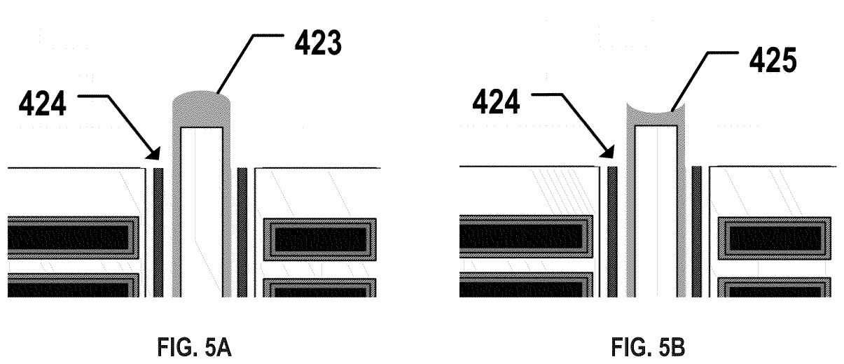

In some implementations, the top end of semiconductor channel 422 exceeding memory film 424 may include a flat surface, as shown in FIG. 4B. That is, points on the top surface of semiconductor channel 422 may be approximately at the same level along the horizontal direction. FIGS. 5A-5B illustrate other configurations of semiconductor channels 422 each extending beyond a memory film in a channel structure, according to some aspects of the present disclosure. In some implementations, the top end of semiconductor channel 422 exceeding memory film 424 may include a tongue profile 423, as shown in FIG. 5A. The term “tongue” may refer to a configuration in which semiconductor channel 422 has a tongue-like feature that protrudes from the edges of the top end of semiconductor channel 422 and may have the most protruding portion approximately at the top center. In other implementations, the top end of semiconductor channel 422 extending beyond memory film 424 may include a concave profile 425, as shown in FIG. 5B. Contrary to the tongue profile, the term “concave” may refer to a configuration in which semiconductor channel 422 extends outward, creating a raised portion at the edges of the top end of the semiconductor channel and may have the lowest portion approximately at the top center. In some implementations, a portion of semiconductor channel 422 at suitable locations of the top end of semiconductor channel 422 may be removed to form tongue profile 423 in FIG. 5A and concave profile in FIG. 5B.

During operation 208 in FIG. 2A, in some implementations, a portion of insulating layer 436 of slit structure 432 (in one example, it may also include a glue layer of slit structure 432) can also be removed to expose slit core 434 of slit structure 432 exceeding memory stack 418. In some implementations, the portion of insulating layer 436 can be removed by applying etchants. The etchants can include any suitable etchants that etch insulating layer 436 selective to slit core 434. For example, insulating layer 436 of slit structure 432 may be etched, stopping at memory stack 418. In some implementations, the etching process(es) of insulating layer 436 can be controlled such that the upper end of slit core 434 is above the upper end of insulating layer 436, according to some implementations. In other words, slit core 434 can extend further beyond memory stack 418 than insulating layer 436. For example, insulating layer 436 may end approximately at the top surface of memory stack 418, while slit core 434 may extend above the top surface of memory stack 418.

More specifically, the upper end of insulating layer 436 of slit structure 432 is not aligned with the upper end of slit core 434 in the vertical direction after the portion of insulating layer 436 is removed during the fabrication process, according to some implementations. In some implementations, the upper end of insulating layer 436 is below the upper end of slit core 434 in slit structure 432, as shown in FIG. 4B. In some implementations, the upper end of insulating layer 436 may be flush with memory stack 418. That is, the vertical level of insulating layer 436 may be approximately identical to the vertical level of memory stack 418. In some examples, the upper end of insulating layer 436 may be above the top surface of memory stack 418. That is, the upper end of insulating layer 436 can be flush with or exceed the top surface of memory stack 418.

During operation 208 in FIG. 2A, the top end of peripheral contact 438 can also be exposed. In some implementations, a portion of filling structure 431 in first semiconductor structure 304 can be removed by applying etchants after or during carrier substrate 302 is removed. The etchants can include any suitable etchants that etch filling structure 431 selective to peripheral contact 438, and the etching time can be controlled. In some implementations, after the portion of filling structure 431 is removed, the top end of peripheral contact 438 may extend beyond the remaining filling structure 431. In some implementations, the removal of filling structure 431, the removal of insulating layer 436 of slit structure 432, and the removal of memory film 424 of channel structure 412 can be performed simultaneously, while in other implementations, they may be performed in a different order, and the present disclosure does not limit thereto.

Returning to FIG. 2A, method 200 may proceed to operation 210, in which a surface treatment (e.g., an activation process) may be performed on the exposed surface of first semiconductor structure 304, e.g., the exposed portion of semiconductor channel 422. In some implementations, heat may be applied on the exposed surface of first semiconductor structure 304 in a confined depth/area. In some implementations, the heat can be transferred to the lower positions of first semiconductor structure 304, and the confined depth/area may be between memory stack 418 and the top surface of first semiconductor structure 304 in the vertical direction. In some examples, the confined depth/area does not extend beyond bonding interface 308 to avoid heating bonding interface 308 and copper interconnects used for connecting first semiconductor structure 304 with second semiconductor structure 306. In some implementations, the heat can be applied and focused by laser and include laser activation.

In some implementations, the activation process(es) can facilitate the subsequent formation of an adhesive layer. In some implementations, the activation process(es) can also enhance Gate-Induced Drain Leakage (GIDL)-induced hole carriers at the bottom select gate (BSG) and top select gate (TSG) during the subsequent erase operations. In some implementations, memory device 400 may utilize GIDL current for efficient erase operations. That is, memory device 400 can be configured to generate GIDL-assisted body biasing when performing an erase operation, according to some implementations. It is understood that one or more of stack conductive layers 414 close to the top end of semiconductor channel 422 (i.e., the source of channel structure 412) can serve as bottom select gate line(s) that is coupled with each BSG, and one or more of stack conductive layers away from the top end of semiconductor channel 422 may be top select gate line(s). The rest of stack conductive layers 414 may serve as word lines.

Returning to FIG. 2A, method 200 may proceed to operation 212, in which an adhesive layer 440 in contact with the exposed portion of semiconductor channel 422 can be formed, as shown in FIG. 4C. In some implementations, adhesive layer 440 may be formed above or on memory stack 418 (e.g., memory stack 418 that may include filling layer 430). In some implementations, adhesive layer 440 may include a Ti/TiN layer, a Ta/TaN layer, a composite layer having a metal material (e.g., tungsten), or the like. In some implementations, the thickness of adhesive layer 440 can be between about 50 Å and about 100 Å. Adhesive layer 440 can be arranged to enhance the adhesion between first semiconductor structure 304 and a conductor layer formed thereafter.

In some implementations, adhesive layer 440 can be formed to cover the exposed portion of semiconductor channel 422. For example, adhesive layer 440 may be formed on the exposed surfaces of semiconductor channel 422, including the top surfaces as well as the sidewall of semiconductor channel 422, as shown in FIG. 4C, so as to increase the contact area. As a consequence, adhesive layer 440 may also have contact with the exposed top end of memory film 424 surrounding semiconductor channel 422. In some implementations, first semiconductor structure 304 of 3D memory device 400 may include adhesive layer 440 that can electrically connect multiple channel structures 412. As a result, adhesive layer 440 can provide electrical connections between the sources of an array of NAND memory strings in the same block, i.e., providing an array common source (ACS).

In some implementations, adhesive layer 440 can also be formed to cover the exposed portion of slit core 434 of slit structure 432. For example, adhesive layer 440 may be formed on the exposed slit core 434 of slit structure 432, including the top surfaces as well as the sidewall of slit core 434, as shown in FIG. 4C, to increase the contact area. Meanwhile, adhesive layer 440 may also have contact with the exposed top end of insulating layer 436 surrounding slit core 434.

In some implementations, adhesive layer 440 can also be formed to cover peripheral contact 438. In some implementations, adhesive layer 440 can be formed to cover the sidewall of peripheral contact 438, and the top end of peripheral contact 438 may extend beyond filling structure 431, as shown in FIG. 4C. In some implementations, adhesive layer 440 can be formed to cover the top end as well as the sidewall of peripheral contact 438. When adhesive layer 440 and peripheral contact 438 can have an electrical connection, the present disclosure does not limit thereto.

In the fabrication process, to form adhesive layer 440, a semiconductor layer or a metal layer may be deposited to have contact with the exposed portion of semiconductor channel 422 and the outer area of semiconductor channel 422 using one or more thin film deposition processes, such as ALD, CVD, PVD, any other suitable processes, or any combination thereof. In some implementations, adhesive layer 440 may be configured to block material diffusion (e.g., silicon/aluminum diffusion between memory stack 418 and a conductor layer formed later).

Returning to FIG. 2A, method 200 may proceed to operation 214, in which a conductor layer 442 in contact with adhesive layer 440 can be formed, as shown in FIG. 4D. In some implementations, one or more conductive materials may be deposited on adhesive layer 440 using one or more thin film deposition processes, such as ALD, CVD, PVD, any other suitable processes, or any combination thereof, to cover adhesive layer 440. In some implementations, the one or more conductive materials may include Al, W, or a combination thereof. In some implementations, a planarization process, such as CMP, can then be performed to remove an excess portion of conductor layer 442. In some implementations, conductor layer 442 can serve as part of the pad structure as well as the backside common source structure.

Method 200 may proceed to operation 216. At operation 216, one or more isolation structures may be formed. In some implementations, one or more first trenches and one or more second trenches may be formed. The one or more first trenches can be part of a first isolation structure 444, while the one or more second trenches can be part of a second isolation structure 446. In some implementations, the one or more first trenches each extending through conductor layer 442 and adhesive layer 440 may be formed in the peripheral region of memory device 400, using wet etching and/or dry etching, such as RIE, to expose filling structure 431 below adhesive layer 440. In some examples, the one or more first trenches can be arranged between two peripheral contacts 438 to electrically insulate the two peripheral contacts 438. In some implementations, the one or more first trenches may be patterned using lithography to be aligned between two peripheral contacts 438, as shown in FIG. 4E. The etching of the one or more first trenches can be configured to completely remove adhesive layer 440 to expose filling structure 431 below. In some implementations, a portion of filling structure 431 below adhesive layer 440 may also be removed. Subsequently, a first spacer may be deposited into the one or more first trenches. In some examples, the first spacer may include a first dielectric material. The first spacer can form first isolation structure 444 to electrically insulate adjacent peripheral contacts 438 in the peripheral region of memory device 400.

In some implementations, one or more second trenches each extending through conductor layer 442 may be formed in a suitable location using wet etching and/or dry etching, such as RIE. In some implementations, the one or more second trenches may be patterned using lithography to be aligned with the top end of slit structure 432, as shown in FIG. 4E. In some examples, the etching of the one or more second trenches can stop at adhesive layer 440 on the top end of slit core 434 to expose adhesive layer 440 below. Subsequently, a second spacer may be deposited into one or more second trenches and may become a part of second isolation structure 446. In some examples, the second spacer may include a second dielectric material. The second dielectric material may be identical to or different from the first dielectric material. Second isolation structure 446 can include the second spacer. In some implementations, the second isolation structure can be arranged to release the stress caused by adhesive layer 440.

In some implementations, one or more pins 448 can be formed in memory device 400. In some examples, one or more openings, by removing a portion of conductor layer 442, using wet etching and/or dry etching, may be formed, as shown in FIG. 4E. Subsequently, a conductive material may be deposited into the one or more openings to form one or more pins 448. At least one of pins 448 can be used to connect with a memory controller that is coupled with a host in a memory system that includes memory device 400.

FIG. 2B illustrates a flowchart of another exemplary method for forming a 3D memory device, according to some aspects of the present disclosure. In the present disclosure, the removal operation of carrier substrate 302 and the portion of memory film 424 can be controlled to ensure that the removal can be done at a suitable depth in the vertical direction. As described above, the removal conditions, such as removing rate and time and the applied removal method, can be adjusted to ensure that the desired depth has been reached. In some implementations, a stop layer between carrier substrate 302 and memory stack 418 can be arranged for a similar purpose. The removal operation(s) can be stopped by the stop layer to minimize the gouging variations among the removal operations of memory film 424 of each channel structure 412.

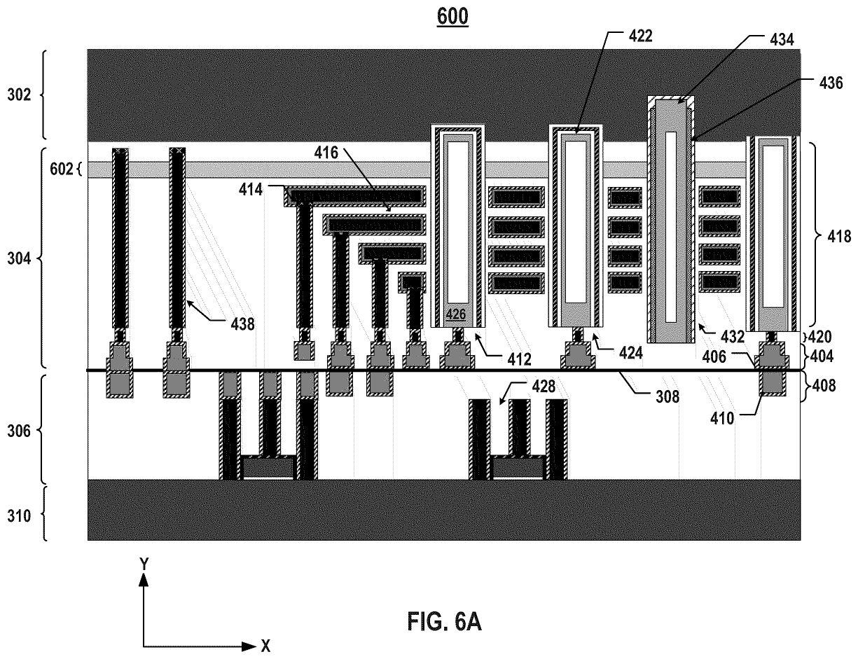

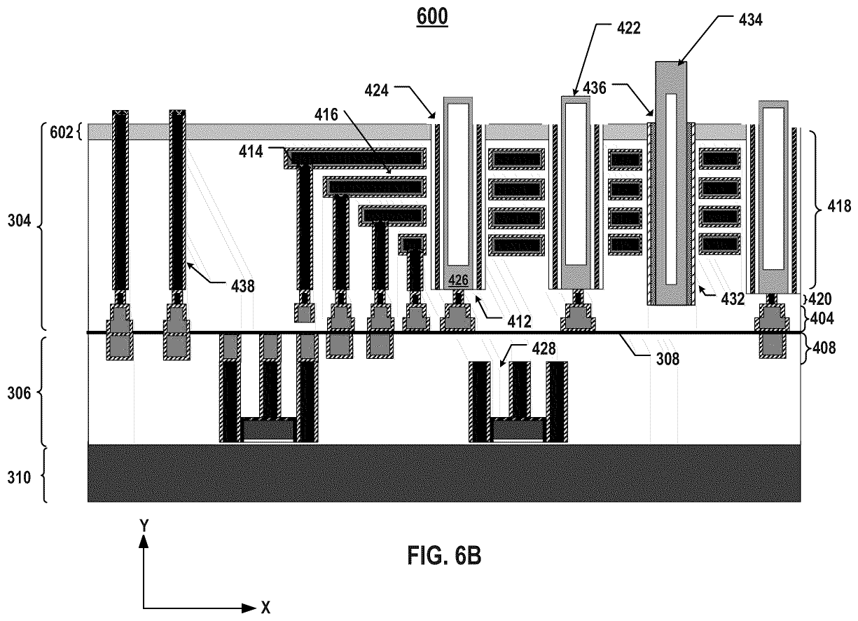

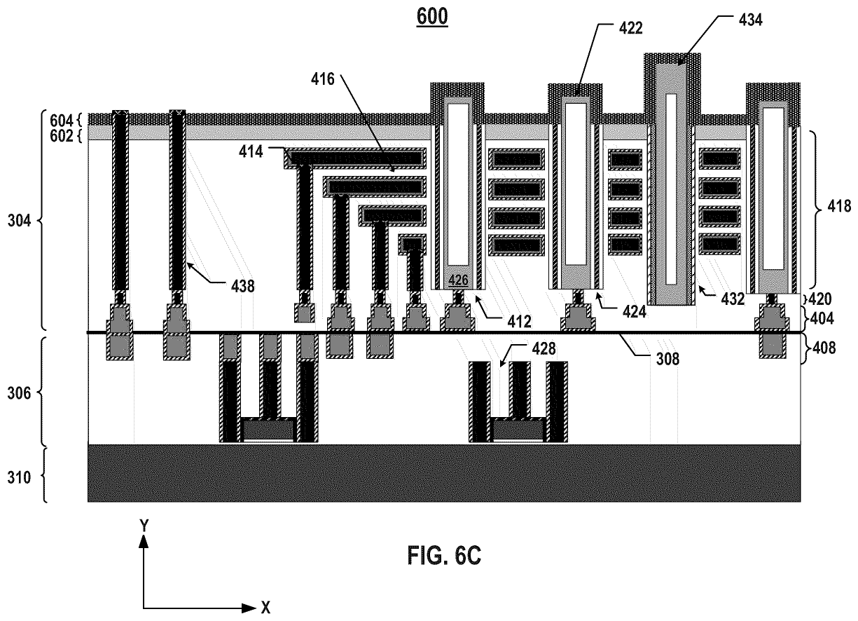

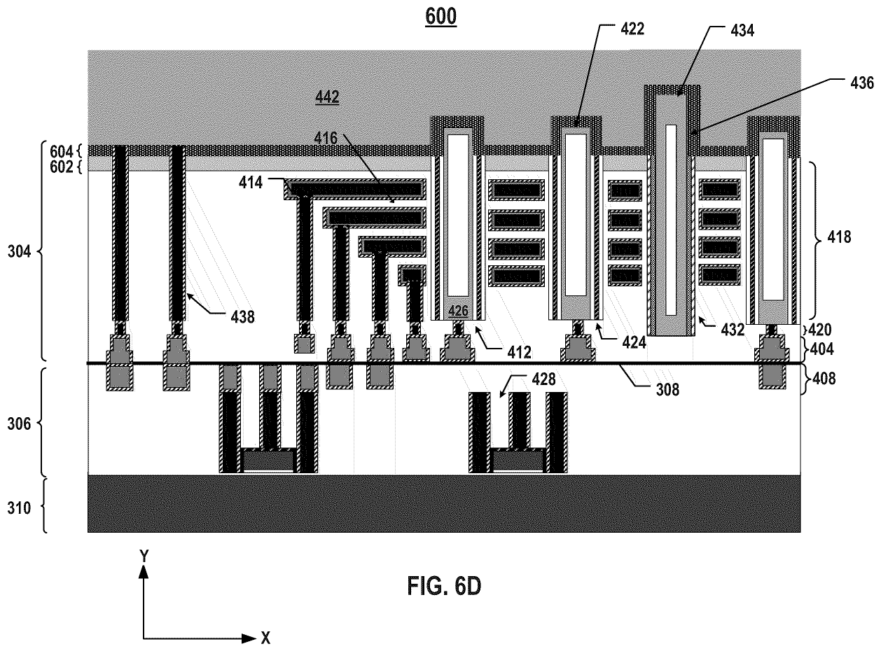

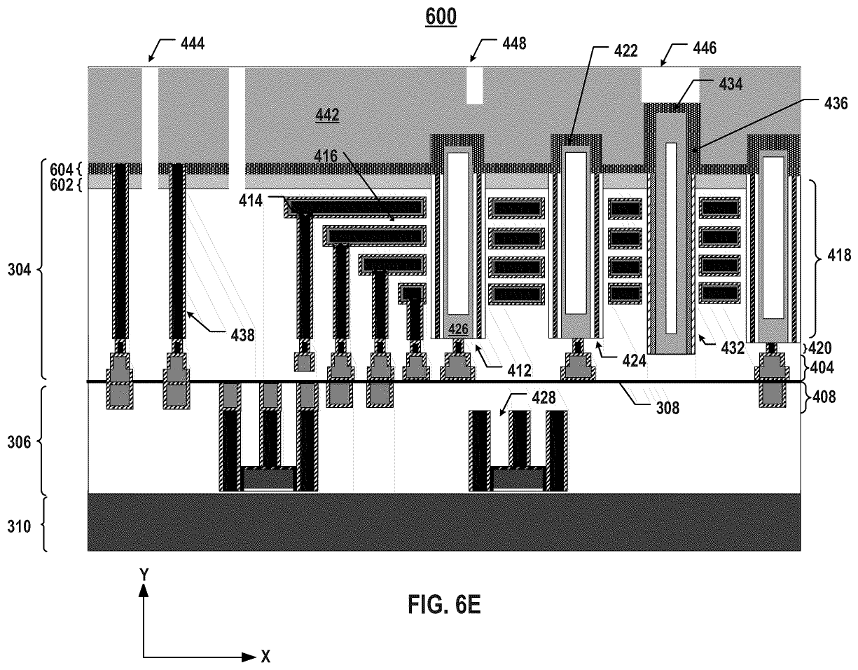

As described above, in forming first semiconductor structure 304 at operation 202 of FIG. 2A, a stack structure including interleaved first dielectric layers (i.e., sacrificial layers) and second dielectric layers (i.e., becoming dielectric layers in memory stack 418 of the subsequent operations) may be formed on carrier substrate 302. In some implementations, forming first semiconductor structure 304 may include forming a stop layer at operation 202A in FIG. 2B. FIGS. 6A-6E illustrate a corresponding fabrication process for forming an exemplary 3D memory device 600 having a stop layer, according to some aspects of the present disclosure. It can be understood that, for ease of illustration, FIG. 2B merely illustrates part of the fabrication processes, and other parts of FIG. 2B may be similar or identical to the operations shown in FIG. 2A.

At operation 202A in FIG. 2B, in some implementations, before forming the stack structure including interleaved sacrificial layers and dielectric layers, a stop layer 602 may be formed above carrier substrate 302. In some implementations, stop layer 602 may be arranged between carrier substrate 302 and the stack structure that is formed later. In the present disclosure, stop layer 602 can be regarded as part of memory stack 418 formed after the gate replacement, while it can be understood that, in some implementations, stop layer 602 may extend laterally to the peripheral region.

In some examples, stop layer 602 may include polysilicon and can be a polysilicon layer, and thus, in the present disclosure, stop layer 602 may be referred to as a top polysilicon layer. In some implementations, besides serving as an etch stop layer, polysilicon layer 602 may also be used as an interconnection layer for connecting a gate in the core region and a gate in the peripheral region. When the stop layer is a conductive layer, the stop layer may be termed the “first conductive layer” in the present disclosure.

In some implementations, polysilicon layer 602 can be formed above carrier substrate 302, before forming the stack structure, using one or more thin film deposition processes including, but not limited to, CVD, PVD, ALD, or any combination thereof. Subsequently, the interleaved sacrificial layers and dielectric layers may be formed above polysilicon layer 602.

Fabrication processes and operations not shown in FIG. 2B may be identical or similar to the fabrication processes and operations with respect to FIG. 2A, in which a channel structure 412, a memory stack 418 replacing the stack structure, a slit structure 432, and one or more peripheral contacts 438 can be formed. In some implementations, any suitable semiconductor components may be additionally formed in first semiconductor structure 304. The present disclosure does not limit thereto. In some implementations, second semiconductor structure 306 having a semiconductor circuit (e.g., a peripheral circuit) can be formed. Subsequently, first semiconductor structure 304 and second semiconductor structure 306 may be bonded using techniques identically or similarly as described above in regard to operation 206 in FIG. 2A.

Returning to FIG. 2B, method 201 may proceed to operation 208A. In some examples, operation 208A in FIG. 2B may be similar to operation 208 in FIG. 2A. Instead of controlling the etching conditions, such as etching rate and time and the etchants applied, to ensure that a desired depth has been reached, at operation 208A in FIG. 2B, polysilicon layer 602 can be applied as, e.g., an etch stop layer when removing memory film 424 of channel structure 412 and insulating layer 436 of slit structure 432 to control the desired remaining depth.

At operation 208A, carrier substrate 302 and a portion of memory film 424 may be sequentially removed to expose a portion of semiconductor channel 422. As illustrated in FIG. 6B, carrier substrate 302 can be completely removed from the backside of memory device 600 (i.e., the top side in FIG. 6B). When/After removing carrier substrate 302, the portion of memory film 424 including the storage layer, blocking layer, and tunneling layer facing and close to carrier substrate 302 can be removed, stopping at polysilicon layer 602, to expose the top portion of semiconductor channel 422 extending beyond memory stack 418. In some examples, semiconductor channel 422 channel may exceed/extend beyond memory film 424, e.g., about 10 nm.

The configuration of semiconductor channel 422, after the portion of memory film 424 is removed, can be the same or similar to that in FIG. 4B. In some examples, the upper end of memory film 424 is below the upper end of semiconductor channel 422 in channel structure 412. In some examples, semiconductor channel 422 exceeding memory film 424 may have the same or similar profile as shown in FIG. 5A or FIG. 5B.

Similarly, a portion of insulating layer 436 of slit structure 432 can also be removed, stopping at polysilicon layer 602, to expose slit core 434 of slit structure 432. In some implementations, slit core 434 can extend further beyond polysilicon layer 602 than insulating layer 436. For example, as shown in FIG. 6B, insulating layer 436 may end approximately at the top surface of polysilicon layer 602, while slit core 434 may extend above the top surface of polysilicon layer 602.

At operation 208A in FIG. 2B, after carrier substrate 302 is removed (and in some examples, a portion of filling structure 431 may also be removed), the top end of peripheral contact 438 may be exposed and extend beyond polysilicon layer 602. In some implementations, the removal of filling structure 431, the removal of insulating layer 436 of slit structure 432, and the removal of memory film 424 of channel structure 412 can be performed simultaneously, while in other implementations, they may be performed in a different order.

The subsequent operations in FIG. 2B may be similar or identical to the operations shown in FIG. 2A. For example, according to operation 210 in FIG. 2A, a surface treatment may be performed on the exposed surface of first semiconductor structure 304, including the exposed semiconductor channel. In the implementation, the surface treatment may include a laser activation. These operations may also be applied to first semiconductor structure 304 having polysilicon layer 602.

Similarly, according to operation 212 in FIG. 2A, an adhesive layer 604 in contact with the exposed portion of semiconductor channel 422 can be formed, as shown in FIG. 6C. In some implementations, adhesive layer 604 may be formed above polysilicon layer 602 in a contact manner. In some implementations, adhesive layer 604 may include a Ti/TiN layer, a Ta/TaN layer, a composite layer having a metal material (e.g., tungsten), or the like. In some implementations, adhesive layer 604 can be formed to cover the exposed portion of semiconductor channel 422. For example, adhesive layer 604 may be formed on the exposed surfaces of semiconductor channel 422, including the top surfaces as well as the sidewall of semiconductor channel 422, as shown in FIG. 6C, to increase the contact area.

In some implementations, first semiconductor structure 304 of 3D memory device 600 may include adhesive layer 604 that can electrically connect multiple channel structures 412. For example, adhesive layer 604 may provide electrical connections between the sources of an array of NAND memory strings in the same block, i.e., providing an array common source (ACS). In some implementations, adhesive layer 604 can be formed to cover slit core 434 of slit structure 432. For example, adhesive layer 604 may be formed on the exposed slit core 434 of slit structure 432, including the top surfaces as well as the sidewall of slit core 434, as shown in FIG. 6C, to increase the contact area. In some implementations, adhesive layer 604 can be formed to cover peripheral contact 438. In some implementations, adhesive layer 604 can be formed to cover the sidewall of peripheral contact 438, and the top end of peripheral contact 438 may extend beyond adhesive layer 604, as shown in FIG. 6C.

Subsequently, according to operation 214, a conductor layer 442 in contact with adhesive layer 604 can be formed, as shown in FIG. 6D. In some implementations, one or more conductive materials may be deposited on adhesive layer 604 using one or more thin film deposition processes, such as ALD, CVD, PVD, any other suitable processes, or any combination thereof, to cover adhesive layer 604. In some implementations, the one or more conductive materials may include Al, W, or a combination thereof. In some implementations, a planarization process, such as CMP, can then be performed to remove an excess portion of conductor layer 442. In some implementations, conductor layer 442 can serve as part of the pad structure as well as the backside common source structure. Subsequently, one or more isolation structures by removing a portion of conductor layer 442 (and may include one or more other layers) can be formed, as shown in FIG. 6E. One or more first trenches each extending through conductor layer 442 and adhesive layer 604 may be formed in the peripheral region of memory device 600. In some implementations, the one or more first trenches may penetrate polysilicon layer 602 and become a part of first isolation structure 444, as shown in FIG. 6E. Other details may refer to corresponding descriptions in regard to FIGS. 4A-4E.

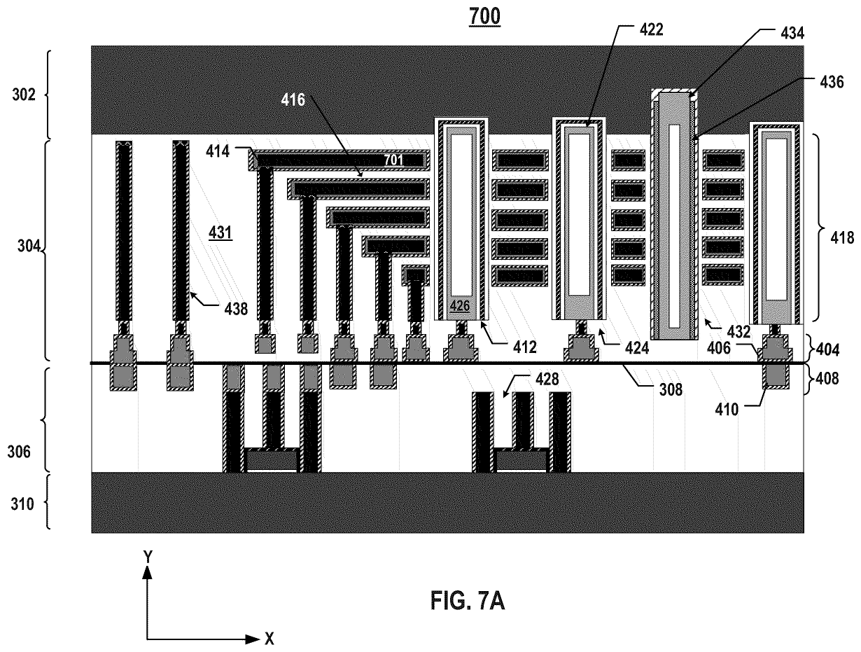

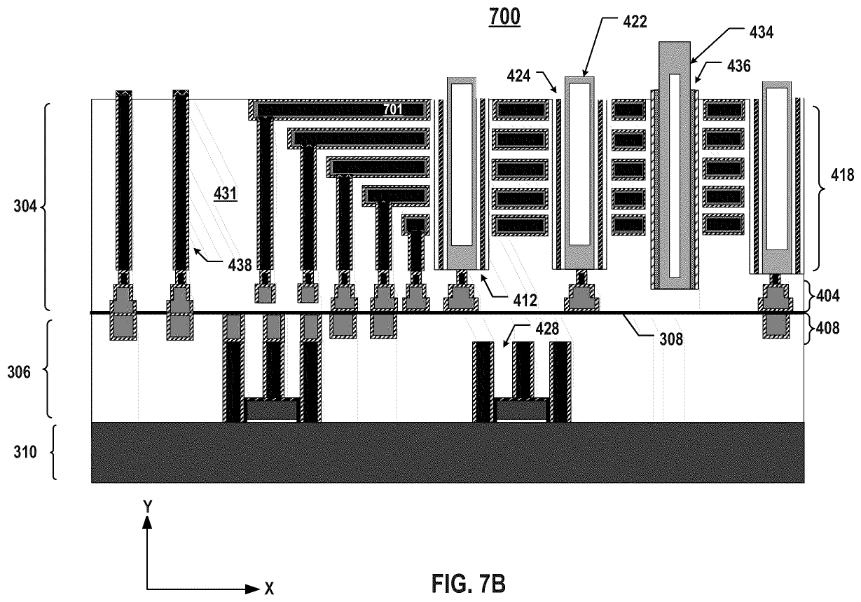

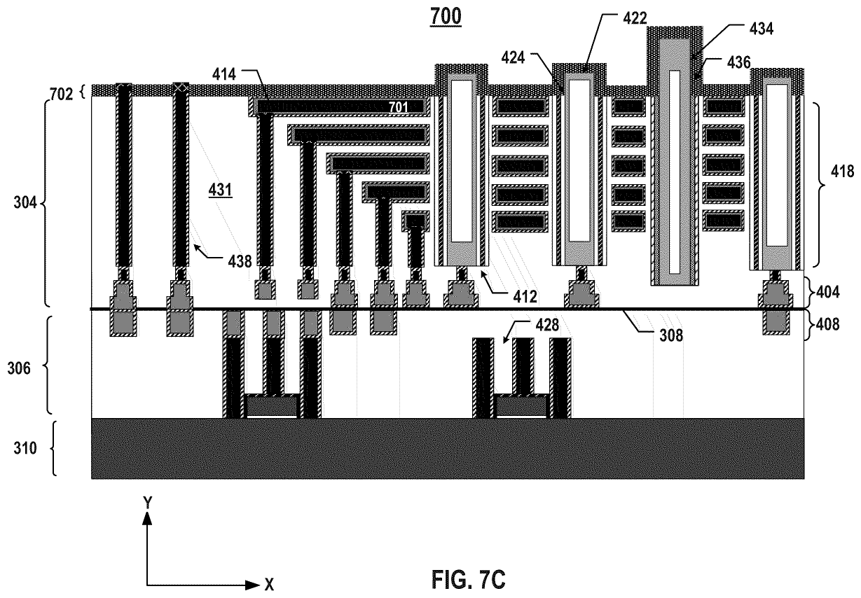

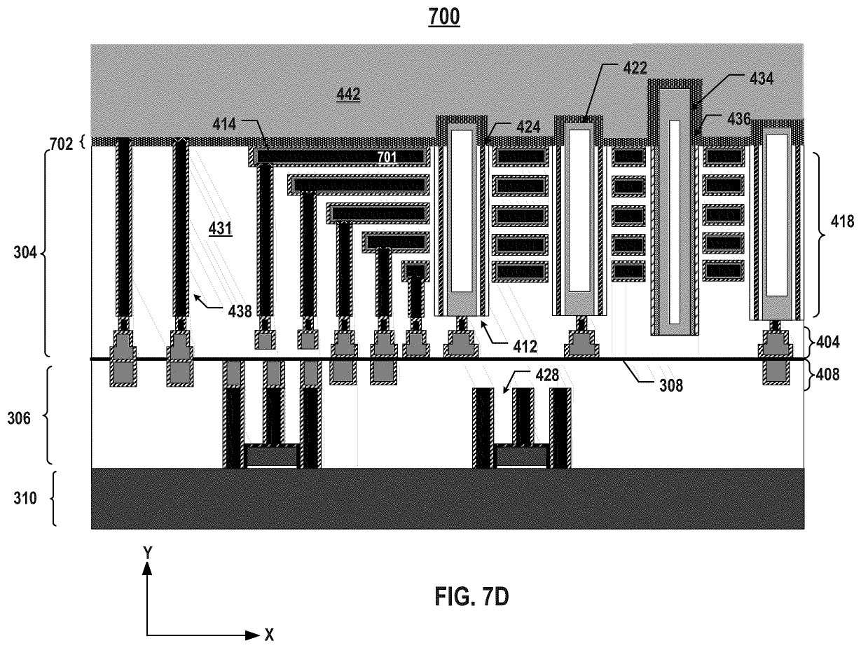

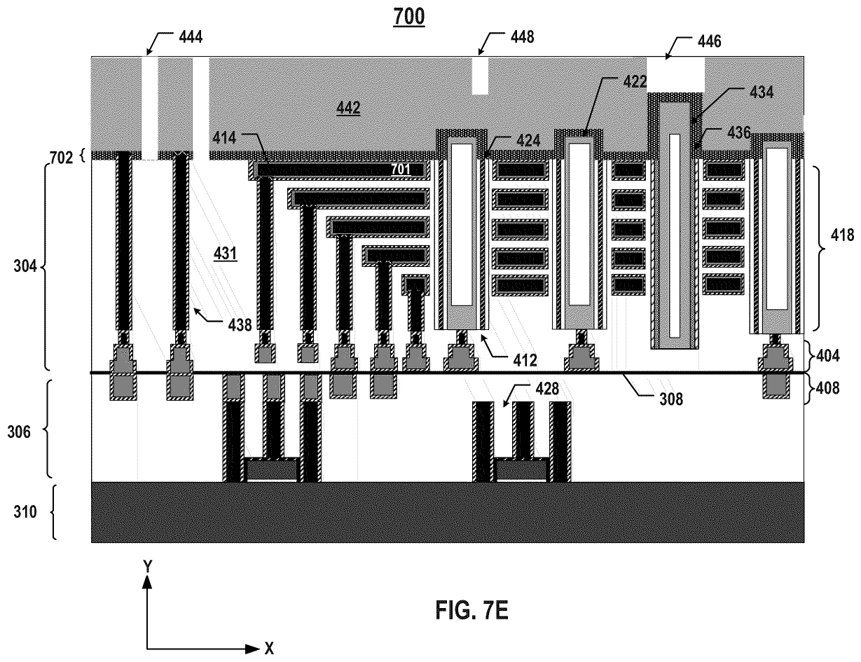

According to FIG. 2B, a stop layer can be arranged above carrier substrate 302 and serve as, e.g., an etch stop layer, to ensure that the removal can be done at a suitable depth in the vertical direction. In some implementations, first semiconductor structure 304 may include the stop layer at operation 202A in FIG. 2B. FIGS. 7A-7E illustrate another fabrication process for forming an exemplary 3D memory device 700 having a stop layer, according to some aspects of the present disclosure.

At operation 202A in FIG. 2B, in some implementations, a stop layer 701 may be formed above carrier substrate 302. In some examples, memory stack 418 formed later can include stop layer 701. As described above, in forming first semiconductor structure 304, a stack structure including a plurality of pairs of a sacrificial layer and a dielectric layer may be formed on carrier substrate 302. Subsequently, a slit opening that extends vertically through the stack structure can be formed. Through the slit opening, a gate replacement can then be performed through the slit opening to replace the stack structure with memory stack 418, which includes stack conductive layer 414 and stack dielectric layer 416. According to operation 202A in FIG. 2B, in some implementations, stop layer 701 can be one of the conductive layers 414 of memory stack 418, which is closer/closest to carrier substrate 302.

Fabrication processes and operations not shown in FIG. 2B may be identical or similar to the fabrication processes and operations with respect to FIG. 2A, in which a channel structure 412, a slit structure 432, and one or more peripheral contacts 438 can be formed. In some implementations, any suitable semiconductor components may be additionally formed in first semiconductor structure 304. The present disclosure does not limit thereto. In some implementations, second semiconductor structure 306 having a semiconductor circuit (e.g., a peripheral circuit) can be formed. Subsequently, first semiconductor structure 304 and second semiconductor structure 306 may be bonded using techniques identically or similarly as described above in regard to operation 206.

Returning to FIG. 2B, method 201 may proceed to operation 208A. In some examples, operation 208A in FIG. 2B may be similar to operation 208 in FIG. 2A. Instead of controlling the etching conditions, such as etching rate and time and the etchants applied, to ensure that a desired depth has been reached, at operation 208A in FIG. 2B, stop layer 701 (or the conductive layer 414 of memory stack 418 closer/closest to carrier substrate 302) can be applied as, e.g., an etch stop layer when removing memory film 424 of channel structure 412 and insulating layer 436 of slit structure 432 to control the desired depth.

At operation 208A, carrier substrate 302 and a portion of memory film 424 may be sequentially removed to expose a portion of semiconductor channel 422. As illustrated in FIG. 7B, carrier substrate 302 can be completely removed from the backside of 3D memory device 700 (i.e., the top side in FIG. 7B). When/After removing carrier substrate 302, the portion of memory film 424 including the storage layer, blocking layer, and tunneling layer facing and close to carrier substrate 302 can be removed, stopping at stop layer 701, to expose the top portion of semiconductor channel 422 extending beyond memory stack 418. In some examples, semiconductor channel 422 may exceed memory film 424, e.g., about 10 nm.

The structure of semiconductor channel 422, after the portion of memory film 424 is removed, can be the same or similar to that in FIG. 4B. In some examples, the upper end of memory film 424 is below the upper end of semiconductor channel 422 in channel structure 412. In some examples, semiconductor channel 422 exceeding memory film 424 may have the same or similar profile shown in FIG. 5A or FIG. 5B.

Similarly, a portion of insulating layer 436 of slit structure 432 can also be removed, stopping at stop layer 701, to expose slit core 434 of slit structure 432. In some implementations, slit core 434 can extend further beyond stop layer 701 than insulating layer 436. For example, as shown in FIG. 7B, insulating layer 436 may end approximately at the top surface of stop layer 701, while slit core 434 may extend above the top surface of stop layer 701.

At operation 208A in FIG. 2B, after carrier substrate 302 is removed, the top end of peripheral contact 438 may be exposed and exceed stop layer 701, according to some implementations. In some implementations, the removal of insulating layer 436 of slit structure 432, and the removal of memory film 424 of channel structure 412 can be performed simultaneously, while in other implementations, they may be performed in a different order.

The subsequent operations in FIG. 2B may be similar or identical to the operations shown in FIG. 2A. For example, according to operation 210 in FIG. 2A, a surface treatment may be performed on the exposed surface of first semiconductor structure 304, including the exposed semiconductor channel. In the implementation, the surface treatment may include laser activation. These operations may also be applied to first semiconductor structure 304 having stop layer 701.

Similarly, according to operation 212 in FIG. 2A, an adhesive layer 702 in contact with the exposed portion of semiconductor channel 422 can be formed, as shown in FIG. 7C. In some implementations, adhesive layer 702 may be formed above stop layer 701 in a contact manner. As a result, conductive layer 414, which serves as stop layer 701 is the conductive layer of memory stack 418 closer/closest to adhesive layer 702. In some implementations, adhesive layer 702 may include a Ti/TiN layer, a Ta/TaN layer, a composite layer having a metal material (e.g., tungsten), or the like. In some implementations, adhesive layer 702 can be formed to cover the exposed portion of semiconductor channel 422. For example, adhesive layer 702 may be formed on the exposed surfaces of semiconductor channel 422, including the top surfaces as well as the sidewall of semiconductor channel 422, as shown in FIG. 7C, to increase the contact area.

In some implementations, first semiconductor structure 304 of 3D memory device 700 may include adhesive layer 702 that can electrically connect multiple channel structures 412. For example, adhesive layer 702 may provide electrical connections between the sources of an array of NAND memory strings in the same block, i.e., providing an array common source (ACS). In some implementations, adhesive layer 702 can be formed to cover slit core 434 of slit structure 432. For example, adhesive layer 702 may be formed on the exposed slit core of slit structure 432, including the top surfaces as well as the sidewall of slit core 434, as shown in FIG. 7C, to increase the contact area. In some implementations, adhesive layer 702 can be formed to cover peripheral contact 438. In some implementations, adhesive layer 702 can be formed to cover the sidewall of peripheral contact 438, and the top end of peripheral contact 438 may extend beyond adhesive layer 702, as shown in FIG. 6C.

Subsequently, according to operation 214, a conductor layer 442 in contact with adhesive layer 702 can be formed, as shown in FIG. 7D. In some implementations, one or more conductive materials may be deposited on adhesive layer 702 using one or more thin film deposition processes, such as ALD, CVD, PVD, any other suitable processes, or any combination thereof, to cover adhesive layer 702. In some implementations, the one or more conductive materials may include Al, W, or a combination thereof. In some implementations, a planarization process, such as CMP, can then be performed to remove an excess portion of conductor layer 442. In some implementations, conductor layer 442 can serve as part of the pad structure as well as the backside common source structure. Subsequently, one or more isolation structures by removing a portion of conductor layer 442 (and may include one or more other layers) can be formed, as shown in FIG. 7E. For example, a portion of conductor layer 442 and a portion of adhesive layer 702 may be removed to expose filling structure 431 below to form one or more first trenches, and a first spacer may be filled into the one or more first trenches to form a first isolation structure. In some implementations, a portion of filling structure 431 may also be removed. Other details may refer to corresponding descriptions in regard to FIGS. 4A-4E.

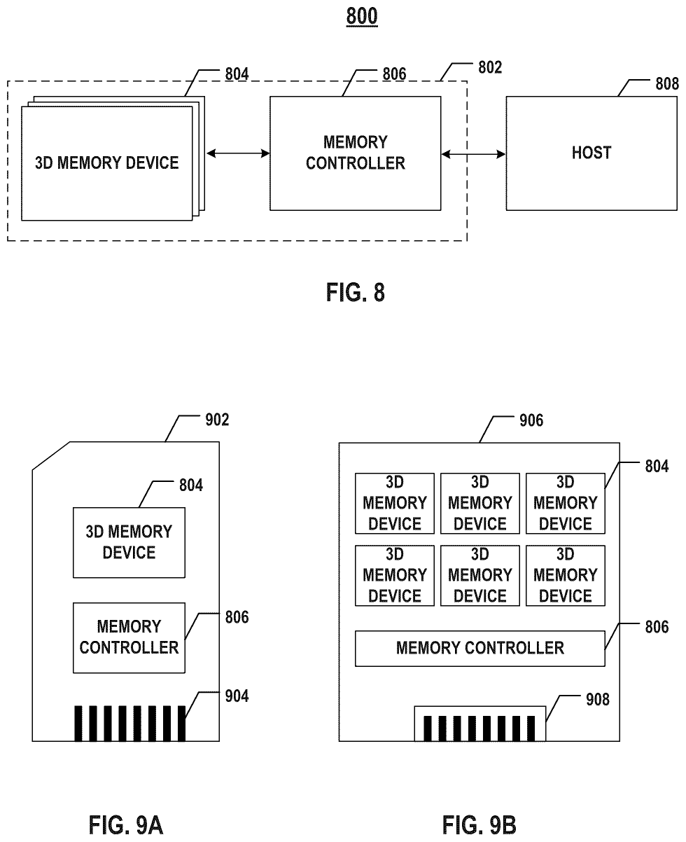

FIG. 8 illustrates a block diagram of an exemplary system 800 having a 3D memory device 804, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more 3D memory devices 804 and a memory controller 806. Host 808 can be a processor of an electronic device, such as a central processing unit (CPU), or a system-on-chip (SoC), such as an application processor (AP).

3D memory device 804 can be any 3D memory devices disclosed herein, such as 3D memory devices 300, 400, 600, and 700 shown in respective figures. In some implementations, each 3D memory device 804 includes a NAND Flash memory. Consistent with the scope of the present disclosure, 3D memory devices 300, 400, 600, and 700 can include a channel structure having a memory film and a semiconductor channel that exceeds the memory film in the first direction. An adhesive layer may be disposed on and in contact with the semiconductor channel that exceeds the memory film, and a conductor layer may be disposed on and in contact with the adhesive layer. Accordingly, the backside pad isolation can be omitted. Meanwhile, Gate Induced Drain Leakage (GIDL) activation can be completed through a surface treatment process (e.g., a laser activation) on the exposed surface after the portion of memory film is removed. As a result, the conductive material can replace the bottom polysilicon layer and serve as part of the pad structure as well as the backside common source structure. Overall, the backside fabrication processes can be simplified, and the cost can also be reduced.

Memory controller 806 is coupled to 3D memory device 804 and host 808 and may be configured to control 3D memory device 804, according to some implementations. Memory controller 806 can manage the data stored in 3D memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Memory controller 806 may be configured to perform any other suitable functions as well, for example, formatting 3D memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented as and packaged into different types of end electronic products. In one example as shown in FIG. 9A, memory controller 806 and a single 3D memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 electrically coupling memory card 902 with a host (e.g., host 808 in FIG. 8). In another example as shown in FIG. 9B, memory controller 806 and multiple 3D memory devices 804 may be integrated into an SSD 906. SSD 906 can further include an SSD connector 908 electrically coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a stack comprising interleaved conductive layers and dielectric layers;
a channel structure extending through the stack in a first direction, the channel structure comprising a memory film and a semiconductor channel that exceeds the memory film in the first direction, the memory film surrounding the semiconductor channel;
an adhesive layer disposed on and in contact with the semiconductor channel that exceeds the memory film; and
a conductor layer disposed on and in contact with the adhesive layer.

2. The 3D memory device of claim 1, wherein the adhesive layer is in contact with a sidewall of the semiconductor channel that exceeds the memory film.

3. The 3D memory device of claim 1, wherein the adhesive layer comprises one of a Ti/TiN layer, a Ta/TaN layer, or a composite layer having a conductive material.

4. The 3D memory device of claim 1, further comprising:
a plurality of peripheral contacts each extending in the first direction and being in contact with the adhesive layer; and
a first isolation structure extending through the conductor layer and the adhesive layer and extending in a second direction perpendicular to the first direction, the first isolation structure comprising a dielectric material, wherein the first isolation structure is arranged between two peripheral contacts of the plurality of peripheral contacts to electrically insulate the two peripheral contacts.

5. The 3D memory device of claim 1, further comprising:
a slit structure extending through the stack in the first direction,
wherein:
the slit structure comprises a slit core and an insulating layer surrounding the slit core, the slit core comprising a conductive material; and
the slit core exceeds the insulating layer in the first direction and is in contact with the adhesive layer.

6. The 3D memory device of claim 1, wherein the stack comprises a first conductive layer in contact with one side of the adhesive layer opposite to the conductor layer.

7. The 3D memory device of claim 6, wherein the first conductive layer is a polysilicon layer.

8. The 3D memory device of claim 6, wherein the first conductive layer is one of the conductive layers of the stack that is closest to the adhesive layer.

9. The 3D memory device of claim 1, wherein the conductor layer comprises at least one of aluminum or tungsten.

10. The 3D memory device of claim 1, further comprising:
a peripheral contact extending in the first direction and being in contact with the adhesive layer, the stack comprising a first conductive layer in contact with the adhesive layer, wherein:
the first conductive layer is a polysilicon layer; and
the polysilicon layer extends in a third direction perpendicular to the first direction, the peripheral contact and the channel structure penetrating the polysilicon layer.

11. A method for forming a three-dimensional (3D) memory device, comprising:
forming a first semiconductor structure that comprises a stack and a channel structure, the channel structure extending through the stack in a first direction and comprising a memory film and a semiconductor channel, the memory film surrounding the semiconductor channel;
removing a portion of the memory film to expose a portion of the semiconductor channel;
forming an adhesive layer disposed on and in contact with the exposed portion of the semiconductor channel that exceeds a remaining portion of the memory film; and
forming a conductor layer disposed on and in contact with the adhesive layer.

12. The method of claim 11, wherein forming the adhesive layer comprises forming the adhesive layer in contact with a sidewall of the semiconductor channel that exceeds the memory film.

13. The method of claim 11, further comprising:
removing a first portion of the conductor layer and a first portion of the adhesive layer to expose the stack and form a first trench, the first trench extending in a second direction perpendicular to the first direction; and
filling the first trench with a dielectric material to form a first isolation structure.

14. The method of claim 11, wherein:
forming the first semiconductor structure further comprises forming a slit structure extending through the stack in the first direction, wherein the slit structure comprises a slit core and an insulating layer surrounding the slit core, and the slit core comprises a conductive material;
the method further comprises removing a portion of the insulating layer at one end of the slit structure to form an exposed slit core that exceeds the insulating layer in the first direction; and
forming the adhesive layer comprises forming the adhesive layer in contact with the exposed slit core.

15. The method of claim 11, wherein removing the portion of the memory film comprises:
removing the portion of the memory film surrounding one end of the semiconductor channel, stopping at the stack.

16. The method of claim 11, wherein:
forming the first semiconductor structure further comprises:
forming a first conductive layer above a substrate; and
forming the channel structure extending through the first conductive layer into the substrate; and
removing the portion of the memory film comprises removing the portion of the memory film, stopping at the first conductive layer.

17. The method of claim 16, wherein:
forming the first conductive layer comprises forming a polysilicon layer above a substrate; and
forming the first semiconductor structure further comprises:
after forming the polysilicon layer, forming a stack structure comprising interleaved sacrificial layers and dielectric layers; and
replacing the sacrificial layers of the stack structure with conductive layers to form the stack.

18. The method of claim 16, wherein:
forming the first semiconductor structure comprises forming a stack structure comprising interleaved sacrificial layers and dielectric layers; and
forming the first conductive layer comprises replacing one of the sacrificial layers that is closest to a substrate with a conductive layer, the first conductive layer comprising the conductive layer.

19. The method of claim 13, further comprising:
before forming the adhesive layer, performing a surface treatment on the exposed portion of the semiconductor channel.

20. A system, comprising:
a three-dimensional (3D) memory device configured to store data and comprising:
a first semiconductor structure comprising:
a stack comprising interleaved conductive layers and dielectric layers;
a channel structure extending through the stack in a first direction, the channel structure comprising a memory film and a semiconductor channel that exceeds the memory film in the first direction, the memory film surrounding the semiconductor channel;
an adhesive layer disposed on and in contact with the semiconductor channel that exceeds the memory film; and
a conductor layer disposed on and in contact with the adhesive layer; and
a second semiconductor structure comprising a peripheral circuit bonded with the first semiconductor structure; and
a memory controller coupled to the 3D memory device and configured to control the 3D memory device.
